(19) United States
(12) Patent Application Publication
(10) Pub. No.: US 2014/0158184 A1
(43) Pub. Date: Jun. 12, 2014

(54) Skirt and Other Devices for Photovoltaic Arrays

(71) Applicants: John Raymond West, San Rafael, CA (US); Tyrus Hawkes Hudson, San Rafael, CA (US); Emil Johansen, San Rafael, CA (US); Ian Capsuto, San Rafael, CA (US); Chad Medcroft, San Rafael, CA (US); Nate Coleman, San Rafael, CA (US); Brian West, San Rafael, CA (US); Brian Atchley, San Rafael, CA (US)

(72) Inventors: John Raymond West, San Rafael, CA (US); Tyrus Hawkes Hudson, San Rafael, CA (US); Emil Johansen, San Rafael, CA (US); Ian Capsuto, San Rafael, CA (US); Chad Medcroft, San Rafael, CA (US); Nate Coleman, San Rafael, CA (US); Brian West, San Rafael, CA (US); Brian Atchley, San Rafael, CA (US)

(73) Assignee: ZEP SOLAR, INC., San Rafael, CA (US)

(21) Appl. No.: 13/960,835

(22) Filed: Aug. 7, 2013

Related U.S. Application Data
(63) Continuation-in-part of application No. 13/316,450, filed on Dec. 9, 2011.
(60) Provisional application No. 61/736,544, filed on Dec. 13, 2012.

(51) Int. Cl. H01L 31/042; H01L 31/048

(52) U.S. Cl. CPC H02S 20/00; H01L 31/0482
USPC 136/251

(57) ABSTRACT

A skirt and other devices for photovoltaic arrays, as well as photovoltaic arrays with a skirt(s) and/or other device(s) installed, related modules, and foothold devices and systems are herein disclosed. Various such embodiments include one or more array skirt(s), T-locks, grip(s), inside and outside corner cap(s), array trim(s), pest abatement screen(s), wire clip(s), foothold(s), groove adaptor bracket(s), magnetic skirt embodiment(s), as well as other structures and embodiments which are herein disclosed.

### CROSS REFERENCES

This application is a continuation-in-part of application Ser. No. 13/316,450, filed Dec. 9, 2011, entitled “Skirt for Photovoltaic Arrays.”

The present application claims the benefit of the filing date of U.S. Provisional Patent Application Ser. No. 61/736,544, filed Dec. 13, 2012 entitled “Ancillary Apparatus, System and Method for Photovoltaic Modules.” The foregoing applications are incorporated by reference in their entirety as if fully set forth herein.

### BACKGROUND

It is common in the art to install photovoltaic (PV) arrays at an offset height above a support surface, such as a roof surface (of shingle, tile, roof membrane or the like). Such a mounting arrangement may provide an air gap beneath the PV array. The offset height distance may provide space for wire management and to allow for PV arrays or PV modules to be mounted above vent pipes and other common roof obstructions. Gaps between PV module frames on the top surface of a PV array may be required to allow space for mounting hardware as well as to allow for dimensional tolerance variation, thermal expansion and the like.

The presence of an openings on the sides of a PV array, as well as between PV module frames on the top surface, may result in organic debris (such as leaves and sticks) entering and becoming trapped under the array, which may in turn result in a fire safety hazard. Rodents/birds/insects and other pests may also enter through these opening and contribute to the accumulation of flammable material through the building of nests, as well as potentially damaging electrical wires contained beneath the array. Regardless of debris, flames from a building fire may enter the air gap beneath an array and compromise the fire safety rating of the roofing material located underneath by trapping hot air, gases, vapor or plasma that typically dissipate if not otherwise confined. Furthermore, in some installations a PV array may be installed such that a gap beneath the PV array allows a viewer to see underneath the PV array, thereby degrading the overall aesthetic appearance of the PV array. Various solutions to these problems are noted below, for example in the section titled “Array Trim” as well as regarding FIG. 103 and its descriptions.

It may be therefore desirable to have a method, apparatus and system for preventing animal intrusion and organic debris from accumulating beneath arrays in addition to impeding open flames from entering the air gap and blocking or limiting the spread of flame over the roof It may also be desirable to have an apparatus, method and system for screening unfavorable view angles beneath a PV array, or otherwise obscuring the area beneath a PV module or portions of a PV array. Some attempts have been made to affix skirt elements to an edge of a PV array for visual screening. However, these prior systems suffer from a number of drawbacks. Various solutions to these problems are noted below, for example regarding FIGS. 73-77C and their descriptions.

Prior skirt systems do not appear to provide adequate structural support. For example, prior systems typically connect a skirt to a mounting foot or a rail of a PV array yet not to an interlock or coupling that may be located in a region where the corners of PV modules meet. Therefore, on a steep roof the weight of the PV array plus other loads, such as snow or an installation technician may not be properly supported, especially in the corner region where couplings may be located. Various solutions to these problems are noted below, for example in the sections titled “Spring Bracket [T Lock]” and/or “Steep Roof Ladder” and/or “Skirt Base,” as well as regarding FIGS. 5-8 and their descriptions.

Prior skirt systems also do not appear to provide a means to accomplish a desired blocking of the spread of flames or a blocking of a view of the area beneath a PV module or array, while allowing for enough airflow to adequately reduce the temperature of the PV array. It is well known in the art that increased PV module temperature reduces total power output. Therefore, it is desirable to provide some means for allowing airflow beneath a PV array. Various solutions to these problems are noted below, for example in the sections titled “Array Skirt” and/or “Array Trim” as well as regarding FIGS. 16-19 and their descriptions.

Prior skirt systems do not appear to provide skirts that adequately block animals and debris since such systems do not typically cover enough of the gap beneath a PV array to be sufficient. For example, roof surfaces are rarely flat yet prior systems provide only a rigid, flat screen, thereby resulting in gaps between the screen and the roof surface. Prior systems also do not provide height adjustability so that a screen may be moved closer to or in contact with a roof surface. Various solutions to these problems are noted below, for example in the section titled “Array Trim” and the section titled “Abatement Screen,” as well as regarding FIG. 103 and its descriptions.

Prior skirt systems require numerous parts which increase the cost of installation for the PV array. Various solutions to these problems are noted below, for example in the sections titled “Array Skirt” and/or “Array Trim” as well as regarding FIGS. 16-19 and their descriptions.

Prior skirt systems also appear not to provide a simple method, apparatus or system for creating a ground bond between a skirt and a PV array. In most, if not all cases of prior systems a separate ground wire would be required to properly ground the skirt, as is required by building regulations in many regions of the world. The parts and labor associated with running a separate ground wire to a skirt is a significant cost. Furthermore, many on-roof grounding systems have suffered problems in the field due to corrosion, which exacerbates the problems of post-installation addition of grounding wires. Various solutions to these problems are noted below, for example in the section titled “Spring Bracket [T Lock]” as well as regarding FIGS. 5-8 and their descriptions.

The instant disclosure also teaches a two-piece skirt embodiment, a magnetic skirt embodiment, a pest abatement screen, an array trim, corner caps, a T-lock, and a foothold. Without limitation, the foregoing may be connected together, one or more may be connected together, or one or more may be connected to a module, and/or one or more may be used in a photovoltaic array or associated with a photovoltaic array. A two-piece skirt embodiment with skirt base generally is a skirt or screen comprised of, by way of example and not limitation, a screen portion and a base portion. A magnetic skirt embodiment generally is a skirt or screen that connects to a bracket or other component using one or more magnets as the exclusive connector or as one of multiple forms of connector. A pest abatement screen generally is a perforated screen that may, without limitation, connect to the outer edge of a PV array by means of a coupling. An array trim generally is a screen that may, without limitation, connect to the outer edge of a PV array by means of a coupling. Corner caps generally are components that extend from the end of one array skirt to the end of another array skirt and may include an angle, turn, curve, or similar non-linear feature. A T-lock generally is a bracket which may be used for, without limitation, holding, securing, positioning or supporting another object. A foothold generally is a device that creates tread or purchase for, without limitation, a foot.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, apparatus, tools, and methods which are meant to be exemplary and illustrative, not limiting in scope. In various embodiments, one or more of the above-described problems have been reduced or eliminated, while other embodiments are directed to other advantages or improvements.

At least one embodiment, by way of non-limiting example, is disclosed of an installed photovoltaic array comprising: a photovoltaic module; a skirt covering at least a portion of an opening beneath the photovoltaic module; a spring bracket connecting the skirt to the photovoltaic module; the spring bracket comprising a base portion, an arm extending outward from the base portion, and a retaining portion near an end of the arm; where the arm acts as a flexible lever to reduce an input force required to rotate the base portion into an installed position and flexing to enable the retaining portion to lock onto the photovoltaic module and the skirt. Various additional embodiments include an installed photovoltaic array as noted above, wherein: (a) the retaining portion bears against at least one of the photovoltaic module(s) and the skirt with a spring force substantially resulting from flexing of the arm; (b) the retaining portion comprises a tab at least partially retained by at least one of the photovoltaic module(s) and the skirt in an installed position; (c) the arm comprises an elongate form extending in a direction substantially parallel to a plane of a top surface of a light receiving side of a photovoltaic laminate of the photovoltaic module; (d) the spring bracket connects to a groove in a frame of the photovoltaic module and/or groove in the skirt; and (e) the spring bracket captures at least a portion of the photovoltaic module.

Another one or more embodiments provides a photovoltaic array skirt, comprising: a skirt portion covering at least a portion of an opening beneath a photovoltaic module; a mounting foot connecting the skirt portion to a support structure; and a slidable retainer at least partially connecting the skirt portion to the mounting foot; wherein the slidable retainer is laterally slidable along the skirt portion to disengage from the mounting foot and the slidable retainer comprises a retaining feature enables an adjustably secure connection of the slidable retainer to the skirt portion prior to connecting the slidable retainer to the mounting foot. Various additional embodiments include: (f) the slidable retainer is laterally slidable along the skirt portion to disengage from the mounting foot and comprises a retaining feature being an adjustably secure connection of the slidable retainer to the skirt portion prior to connecting the slidable retainer to the mounting foot; and (g) the slidable retainer is installed by snapping onto the skirt portion then sliding into engagement with the mounting foot.

And yet another further one or more embodiments provide a photovoltaic array, comprising: a photovoltaic module having a frame; a skirt bracket, skirt or trim (commonly referred in the text below as a “trim”) removably connected to the skirt bracket; and a coupling comprising a first engaging portion connected to the frame and a second engaging portion connected to the skirt bracket; wherein the coupling is adjustably positionable along a length of the frame.

And, yet further one or more embodiments provide a photovoltaic module, comprising: a frame supporting a photovoltaic laminate; a screen coupling connected to a groove in the frame, the screen coupling comprising a key portion permitting insertion of the key into a photovoltaic module frame in a first position and preventing rotation of the key inside the frame in a second position; and a screen connected to the screen coupling; wherein the screen covers at least a portion of an opening beneath the photovoltaic module when the photovoltaic module is mounted to a support structure.

Even yet another one or more embodiments provides a foothold system for use on a sloped roof, comprising: a first flashing block comprising a hole; a second flashing block comprising a hole; a moveable foothold comprising a hook portion removably inserted into the first flashing block hole and a lower portion extending down-roof from the hook portion and comprising a step portion; wherein the moveable foothold is moveable from the first flashing block to the second flashing block via unhooking the hook portion from the first flashing block and hooking the hook portion to the second flashing block. Various additional embodiments include: (h) the flashing blocks further comprising a mounting portion for receiving a mounting foot for a photovoltaic array; and (i) the step portion being sized to receive and support a weight of a foot of a human working on the sloped roof.

The following embodiments and aspects thereof are described and illustrated in conjunction with systems, apparatus, tools, and methods which are meant to be exemplary and illustrative, not limiting in scope. In various embodiments, one or more of the above-described problems have been reduced or eliminated, while other embodiments are directed to other advantages or improvements. In addition to the exemplary aspects and embodiments described above, further aspects and embodiments will become apparent by reference to the figures and by study of the following detailed descriptions.

### BRIEF DESCRIPTION OF THE DRAWINGS

Demonstrative embodiments are illustrated in referenced figures and drawings. It is intended that the embodiments and figures disclosed herein are to be considered illustrative rather than restrictive.

FIG. 1A shows a perspective view of a PV array on a roof.

FIG. 1B shows a close-up of the frame of a PV module connected to a mounting foot in FIG. 1A.

FIG. 1C shows a close-up of the frames of two PV modules connected to an interlock in FIG. 1A.

FIG. 2 shows a perspective view of a PV array with array skirts on a roof.

FIG. 3A, FIG. 3B, FIG. 3C, and FIG. 3D show a side view of a progression of an array skirt and a PV module connecting to a coupling that is affixed to a mounting foot.

FIG. 3E shows a top-down angled view of FIG. 3C.

FIG. 4A and FIG. 4B show a perspective view of a progression of the installation of anti-rotation components into an interlock connected to two array skirts.

FIG. 5 is an exploded view of the components that connect two adjacent array skirts to one another using an interlock.

FIG. 6 and FIG. 7 show a perspective view of an array skirt connecting to a coupling and to an adjacent array skirt using an interlock.

FIG. 8A shows a perspective view of a completed PV array.

FIG. 8B shows a detail view of the connection between two adjacent array skirts and two adjacent PV modules of FIG. 8A.

FIG. 9, FIG. 10, FIG. 11 and FIG. 12 show a perspective view of the progression of the installation of a PV array with an array skirt.

FIG. 13A is a perspective view of a PV array with a louvered array skirt.

FIG. 13B is a detail view of the encircled area in FIG. 13A.

FIG. 14A is a perspective view of a PV array with an array skirt and side screens.

FIG. 14B is a detail view of the encircled area in FIG. 14A

FIG. 15 is a perspective view of a PV array with a skirt and fire-barrier walls.

FIG. 16 and FIG. 17 show a side view of an array skirt with louvers connecting to a coupling affixed to a foot.

FIG. 18 shows a perspective view of FIG. 17.

FIG. 19 shows a side view similar to FIG. 17 but the coupling and attached array skirt are seated lower on the foot.

FIG. 20 shows a perspective view of a PV array with adjacent array skirts that connect laterally using a pin.

FIG. 21 is a side view of the array skirt shown in FIG. 20.

FIG. 22A shows a perspective view of a single-piece array skirt connected to a PV module.

FIG. 22B is a detail view of the encircled area in FIG. 22A.

FIG. 23 and FIG. 24 show a side-view progression of the installation of a single-piece array skirt connecting to a PV module.

FIG. 25 is a perspective view of an array skirt connected to a PV module using a spring clip.

FIG. 26 and FIG. 27 show a side-view progression of an array skirt connecting to a PV module using a spring clip.

FIG. 28 is a detail view of the encircled area in FIG. 25.

FIG. 29 is a perspective view of a spring clip.

FIG. 30A is a perspective view of an array skirt connecting to a PV module using an engagement clip.

FIG. 30B is a detail view of the encircled area in FIG. 30A.

FIG. 31 and FIG. 32 show a side-view progression of an array skirt connecting to a PV module using an engagement clip.

FIG. 33 is a perspective view of an engagement clip.

FIG. 34A is a perspective view of an array skirt attached to a PV module using a rotatable attachment clip.

FIG. 34B is a detail view of the encircled area in FIG. 34A.

FIG. 35 and FIG. 36 show a side view progression of the installation of an array skirt onto a PV module using a rotatable attachment clip.

FIG. 37 is a perspective view of a rotatable attachment clip.

FIG. 38 and FIG. 39 show a perspective view progression of the installation of a rotatable attachment clip into the groove of a PV module.

FIG. 40 shows a perspective view of a screen connected to a PV module using a spring clip.

FIG. 41 is a perspective view of a spring clip.

FIG. 42 shows a perspective view of spring clips connected to the reverse side of a screen.

FIG. 43 is a side view of a spring clip connected to the groove of a PV module.

FIG. 44A is a perspective view of side screens installed on a PV module using frame engagement clips.

FIG. 44B is a detail view of the encircled area in FIG. 44A.

FIG. 45 is a perspective view of a side frame engagement clip.

FIG. 46 is a perspective view of a corner frame engagement clip.

FIG. 47 is a side view showing a frame engagement clip connected to the groove of a PV module.

FIG. 48 is a perspective drawing of a screen connected to module gap spring clips.

FIG. 49 is a perspective drawing of a screen connected to the grooves of two adjacent PV modules using module gap spring clips.

FIG. 50 is a perspective view of a module gap spring clip.

FIG. 51 is a cutaway view of a module gap spring clip installed between two adjacent PV modules.

FIG. 52 and FIG. 53 show a side view progression of a PV module connecting to a coupling to which an extrusion span jig is also connected.

FIG. 54 is a perspective drawing of an array skirt attached to a PV module using an extrusion span jig.

FIG. 55 shows a side view of an array skirt attached to a PV module using an extrusion span jig.

FIG. 56 is a perspective view of mounting feet installed on a rooftop surface.

FIG. 57 is a perspective drawing of an extrusion span jig installed on mounting feet.

FIG. 58 and FIG. 59 show a perspective view progression of PV modules forming an array with an array skirt connected using an extrusion span jig.

FIG. 60 and FIG. 61 show a side view progression of an array skirt connected to a flexible screen material connecting to a coupling.

FIG. 62 is a perspective view of an array skirt connected to a flexible screen material connected to a PV module.

FIG. 63 shows a side view of an array skirt connected to a flexible screen material connected to a PV module.

FIG. 64A shows an array skirt with a scalloped lower portion connected to a PV array.

FIG. 64B is a detail view of the encircled area in FIG. 64A

FIG. 65 shows a top view of a PV array with an interlock and anti-rotation components installed.

FIG. 66 is a perspective view of an accessory component assembly with an electrical box connecting to a PV module and using anti-rotation components.

FIG. 67 is a perspective view of an array skirt connected to a PV module using a spring bracket.

FIG. 68 is a perspective view of a spring bracket connecting to a PV module.

FIG. 69 is a top view of a spring bracket.

FIG. 70 is a side view of a spring bracket.

FIG. 71 is a perspective view of a spring bracket.

FIG. 72 is an orthogonal view of a spring bracket.

FIG. 73 is a perspective drawing of an array skirt.

FIG. 73A is a side view of an array skirt.

FIG. 74 is a perspective drawing of an array skirt from the groove side.

FIG. 75 is a perspective drawing of a grip.

FIG. 76 is a side view drawing of a grip attached to an array skirt.

FIG. 76A is a side view of an array skirt connecting to the coupling of a leveling foot.

FIG. 76B is a side view of an array skirt connected to the coupling of a leveling foot.

FIG. 77A is a perspective view of an array skirt connected to the coupling of a leveling foot.

FIG. 77B is a perspective view of a grip connected to an array skirt and the array skirt connected to the coupling of a leveling foot.

FIG. 77C is a perspective view of an array skirt connected to the coupling of a leveling foot and secured by a grip that is connected to both the array skirt and the coupling of the leveling foot.

FIG. 78A is a perspective view of an array skirt connected to the coupling of a leveling foot.

FIG. 78B is a perspective view of a grip connected to an array skirt and the array skirt connected to the coupling of a leveling foot.

FIG. 78C is a perspective view of an array skirt connected to the coupling of a leveling foot and secured by a grip that is connected to both the array skirt and the coupling of the leveling foot.

FIG. 79A is a perspective view of a rotating trim bracket (also known as a skirt bracket) in its open or unengaged position.

FIG. 79B is a side view of a rotating trim bracket (also known as a skirt bracket) in its open or unengaged position.

FIG. 79C is a perspective view of a rotating trim bracket (also known as a skirt bracket) in its closed or engaged position.

FIG. 79D is a side view of a rotating trim bracket (also known as a skirt bracket) in its closed or engaged position.

FIG. 80A is a perspective view of a rotating trim bracket (also known as a skirt bracket) connecting to a groove with a support plate rotated 90 degrees so it extends parallel to the module.

FIG. 80B is a side view of a rotating trim bracket (also known as a skirt bracket) connecting to a groove with a support plate rotated 90 degrees so it extends parallel to the module.

FIG. 80C is a side view of a rotating trim bracket (also known as a skirt bracket) connected to a groove with a support plate rotated 180 degrees so it extends away from the module.

FIG. 81 is a side view of a rotating trim bracket (also known as a skirt bracket) attached to a groove with a support plate extending away from the module with a skirt attached.

FIG. 82 is a side view of a skirt base.

FIG. 83 shows a side view of a T-bar.

FIG. 84 is a side view of a skirt base with a T-bar installed.

FIG. 85 is a side view of a skirt base with a skirt installed.

FIG. 86 is a perspective view of a tile hook.

FIG. 87 is an alternate perspective view of a tile hook.

FIG. 88 is a side view of a tile hook.

FIG. 89A is a perspective view of a grip.

FIG. 89B is an orthogonal view of a grip.

FIG. 90 is a side view of a grip connected to an array skirt.

FIG. 91A is a perspective view of a grip connected to an array skirt and the array skirt connected to the coupling of a leveling foot.

FIG. 91B is a perspective view of an array skirt connected to the coupling of a leveling foot and secured by a grip that is connected to both the array skirt and the coupling of the leveling foot.

FIG. 92A is a perspective view of a grip connected to an array skirt and the array skirt connected to the coupling of a leveling foot.

FIG. 92B is a perspective view of an array skirt connected to the coupling of a leveling foot and secured by a grip that is connected to both the array skirt and the coupling of the leveling foot.

FIG. 93A is a perspective view of a corner cap.

FIG. 93B is an orthogonal view of a corner cap.

FIG. 93C is a rear perspective view of a corner cap.

FIG. 94A shows a corner cap aligned to connect to an array skirt.

FIG. 94B shows a corner cap connected to an array skirt.

FIG. 94C shows a corner cap aligned to connect to two array skirts.

FIG. 94D shows a corner cap connected to two array skirts.

FIG. 95A is a perspective view of a corner cap.

FIG. 95B is an orthogonal view of a corner cap.

FIG. 95C is a rear perspective view of a corner cap.

FIG. 95D shows a corner cap aligned to an array skirt.

FIG. 95E shows a corner cap connected to an array skirt.

FIG. 96A is a top view of a corner cap.

FIG. 96B is a perspective view of a corner cap.

FIG. 97A is a perspective view of an interlock aligned to connect two adjacent array skirts.

FIG. 97B is a perspective view of an interlock inserted into the grooves of two adjacent array skirts.

FIG. 97C is a perspective view of an interlock inserted into the grooves of two adjacent array skirts with a coupling about to be secured to an array skirt using a tool.

FIG. 97D is a perspective view of an interlock secured to two adjacent array skirts using a tool.

FIG. 97E is a perspective view of two adjacent array skirts connected by an interlock aligning to connect to the couplings of leveling feet.

FIG. 97F is a side view of a PV module attaching to the coupling of a leveling foot to which an array skirt is connected.

FIG. 97G is a side view of a PV module attached to the coupling of a leveling foot to which an array skirt is connected.

FIG. 97H is a perspective view of a PV module attaching to the coupling of a leveling foot to which an array skirt is connected, adjacent to a PV module that has already connected to the PV array.

FIG. 97I is a perspective view of three adjacent PV modules and three adjacent leveling skirts connected to the couplings of leveling feet to form a PV array.

FIG. 98A is a perspective view of an array trim.

FIG. 98B is a rear perspective view of an array trim.

FIG. 98C is a side view of an array trim.

FIG. 99A is a perspective view of a skirt bracket.

FIG. 99B is a side view of a skirt bracket.

FIG. 100 is a side view of an array trim attached to a skirt bracket, a coupling, and the groove of a PV module frame.

FIGS. 101A and 101B are views of a screen coupling.

FIG. 102 is an isometric view of a screen.

FIG. 103 is a perspective view of an abatement screen installed on a PV module.

### DETAILED DESCRIPTION

### Terms

While various terms may have their ordinary meaning or particular meaning in the art, for ease of understanding there is provided herein, both below and at other locations in this specification, a non-limiting explanation as to the minimum scope intended for understanding of the present specification. Terms may be in singular or plural or any tense while retaining the same general meaning.

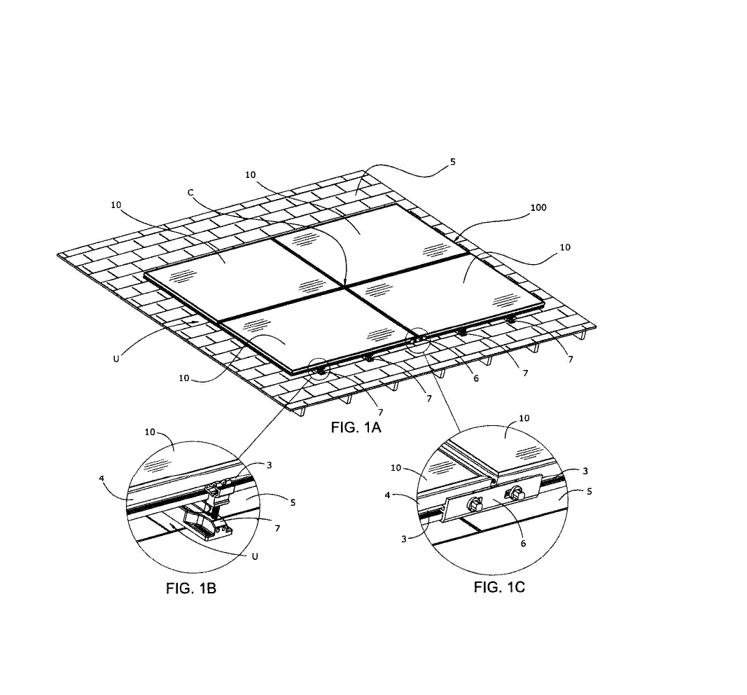

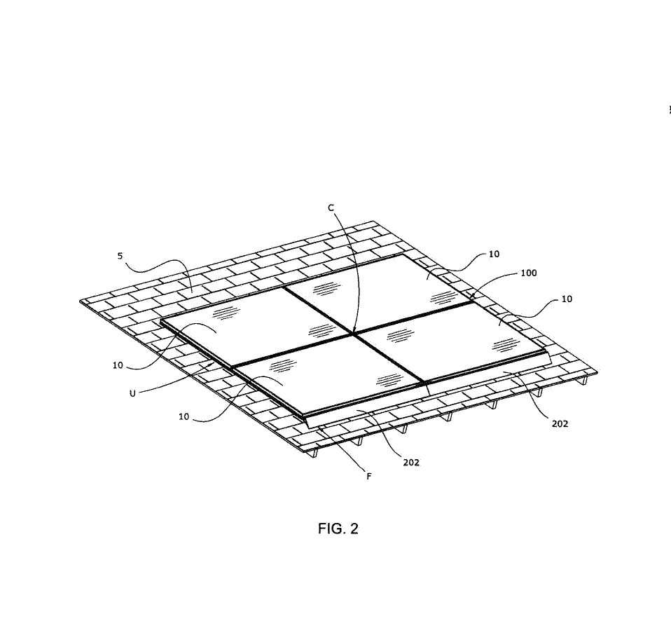

Adjacent refers to being positioned next to or adjoining or neighboring, or having a common vertex or common side. Thus, adjacent PV panels would include PV panels that have one side close to (from a few inches apart to abutting) and facing one side of another PV panel, such as shown in FIGS. 1, 1B and 2. Sometimes, but not always, the corners of adjacent panels align; so four adjacent panels would have one corner each that nearly or actually touch the other three (3) corners, such as exemplified at Point C in FIGS. 1A and 2, and its descriptions.

Affix refers to attaching or fastening something to something else, where attributes of the attachment may be mobile and mutable or immobile and immutable. This is exemplified in FIG. 75A and its descriptions, where a grip is affixed to an array skirt.

Angled louver refers to a defined opening in an item's surface having fixed or movable and usually horizontal slats or blades for permitting air and/or light to pass through the surface having the louver(s). Louver(s) may also refer to the narrow opening(s) formed by the slat(s) or may refer to the slat(s) themselves. Angled louver therefore refers to an item having a surface where one or more louvers is placed or formed in such a way that the louver(s) are inclined at an angle of 1-179 degrees to the surface of the item, such as exemplified at feature 79 in FIGS. 13A, 13B, and 18, and its descriptions.

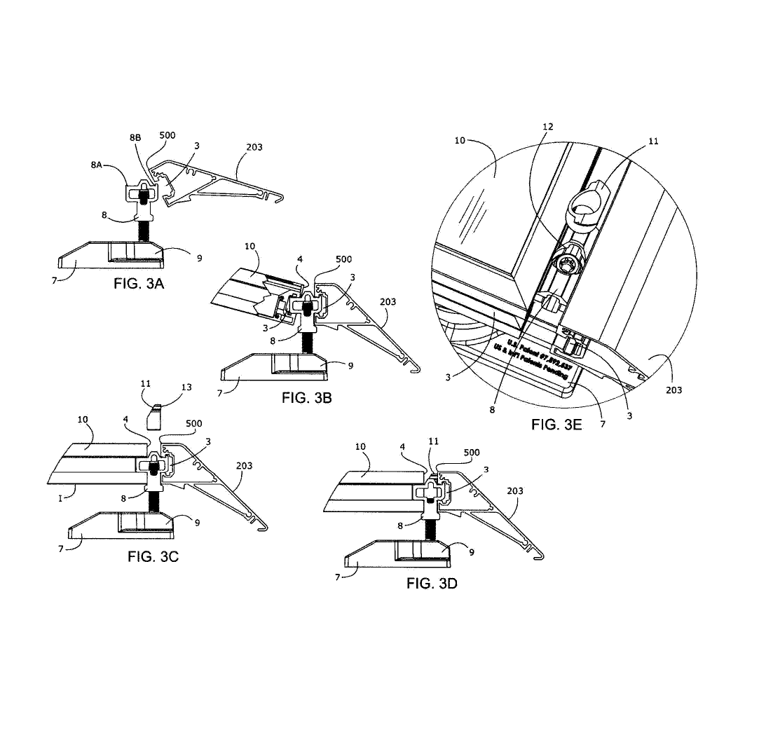

Anti-rotation component refers to a device, item, feature or portion of an item that slows, minimizes, inhibits or stops that act or process of turning around a center or an axis. Such anti-rotation may be total, or may permit some minimal amount of rotation, usually not to exceed 5 degrees of rotation from an initial position. Such an anti-rotation component is exemplified as component 11 in FIGS. 3C and 7, and its descriptions.

Beneath a PV module or PV array refers to the area extending or directly underneath or below a PV module when it is positioned near a support surface, such as a roof For a PV module secured or held above an essentially planar surface, the area beneath would usually include the area of a shadow cast on the planar surface by a light source (such as the sun) projecting from directly above the PV Module. Such an example of an area beneath a PV module is exemplified at Area U in FIGS. 1A, 1B and 2, and its descriptions.

Block refers to obstructing or impeding progress or the making of a flow or passage through either difficult or impossible to traverse, usually by placing obstacles in the way. As an example, to block a spread of flame would include objects that would limit, minimize, reduce, inhibit, obstruct or impede the spreading, propagation or traversal of flame, smoke or high heat in an area, such as under a PV array (usually between a PV array and a support surface, such as a roof). One such block would be a PV array skirt exemplified as skirts 202 and 203 in FIGS. 2 and 3A-3D, and its descriptions.

Bottom refers to the lowest or deepest portion or the portion furthest from the top, as well as the under-side or lower side of an item. Thus, the bottom of a skirt would be that portion, usually resembling an edge, of the skirt that is closest to or in contact with a support surface, such as a roof. One such bottom of a skirt is exemplified at Area F in FIG. 2, and its descriptions. Also, the bottom of a PV module or PV array is that area, usually a surface, that is closest to the support surface, which often defines the upper edge of an area beneath a PV module or PV array. One such bottom of a PV module or PV array is exemplified at location E in FIG. 3C, and its descriptions.

Bracket refers to a simple, essentially rigid structure in the general shape of an L, one arm of which extends approximately 70-110 (often close to 90) degrees from the other arm. A Bracket is often an overhanging member that projects from a structure (such as a portion of a wall or frame) and may be designed to support a load with a vertical component, such as a skirt. A bracket may also refer to a fixture projecting from a wall, column, frame or the like which may be used for holding, securing, positioning or supporting another object. One such bracket for supporting a skirt is exemplified as clip 722 in FIG. 33, and its descriptions.

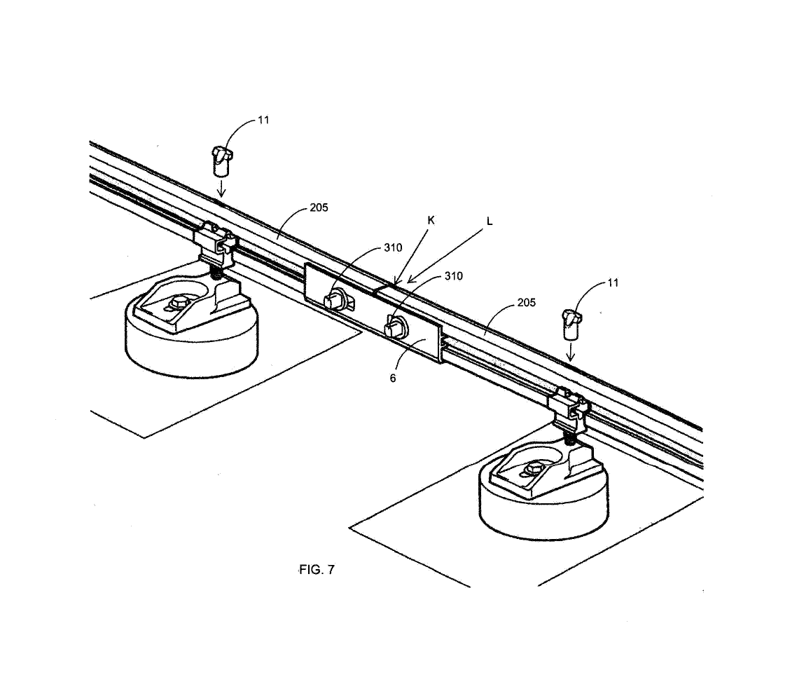

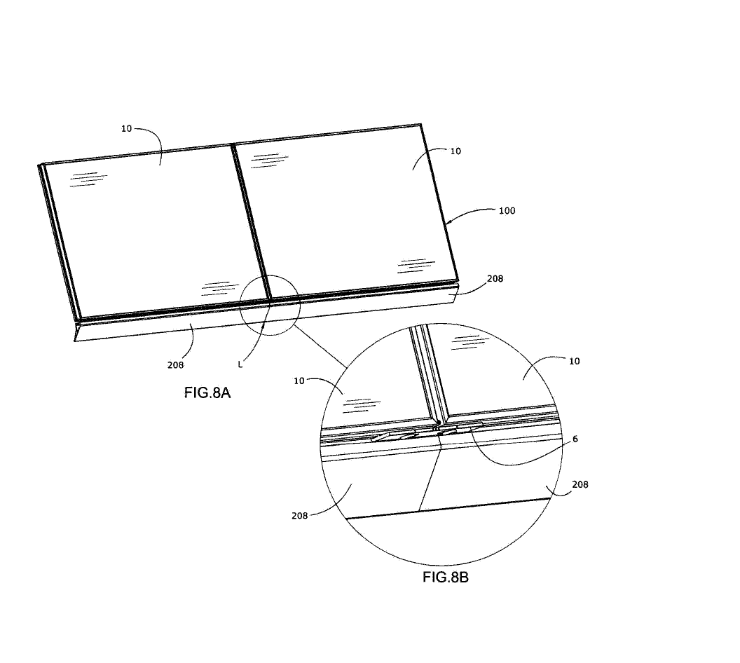

Collinear refers to points, areas or items passing through or lying on the same essentially straight line, or creating a common or coaxial line. Collinear may also refer to sharing a common line, such as two intersecting planes. One example of collinear items would be collinear skirts, which would have its longest dimension (length) extend from end-to-end in an essentially linear manner, such as along an edge of a PV module or PV array, as exemplified at Area L in FIGS. 7 and 8A, and its descriptions.

Complementary screen(s) refers to one or more additional screen(s) (a screen may be in the form of traditional sieve-type or other screen(s), hole(s), perforation(s), louver(s) or the like which are herein more generally referred to as a “screen”, “screens” or “screen(s)”) commonly used to partially or fully block a view past the screen or provide some rigidity while often permitting air (or other fluid) to flow through the screen). Complementary screen(s) form or serve as a complement with a first screen, which may have an effect such as to enhance, emphasize or complete the screening provided by a primary or first screen. One example of complementary screen(s) would be additional screen(s) placed on minor or narrower surfaces of a skirt, rather than the primary or first screen which is usually placed on the largest or primary surface. Some screens in a skirt are exemplified at side screen 214A in FIG. 14B, and its descriptions. Some complementary screens in a skirt are exemplified at screen 370 in FIG. 62, and its descriptions.

Connecting, connects, or connect refers to linking, joining, uniting or fastening two or more things together, to become joined or united. Connecting is exemplified in FIG. 75A and its descriptions.

Connector refers to an object, item, mechanism, apparatus, combination, feature, link or the like that links, joins, unites or fastens two or more things together. The term connector may also include a device, an object, item, mechanism, apparatus, combination, feature, link or the like for keeping two parts of an electric or electronic circuit in contact. A connector is exemplified at feature 10027 in FIG. 100 and its descriptions.

Contour refers to an outline representing, defining or bounding the shape or form of a figure, object, body, mass or surface. As an example, a support surface outline would have a contour being the topography of its uppers surface. For a support surface that is a flat roof, the contour would be essentially a line in the direction normal to the roof incline; but for a tile roof (such as clay roofing tile shaped like a longitudinal segment of a cylinder) the contour would be essentially shaped like a sine-curve (with a slightly different, half-circle, arc) in the direction normal to the roof incline. Some screens that follow a contour of a support surface, such as a roof, are exemplified at skirt 264 in FIGS. 64A and 64B, and its descriptions.

Couple refers to joining, linking, connecting or mating two or more objects or items, mechanisms, objects, things, structures or the like together. For example, two skirts may be coupled together, as exemplified at Area K in FIG. 7, and its descriptions.

Coupling refers to an object, item, apparatus, combination, feature, link or the like that couples, joins, links, mates or connects two things together. For example, two skirts may be coupled together by a coupling device, as exemplified at interlock 6 in FIG. 7, and its descriptions.

Disengage refers to detaching, freeing, loosening, extricating, separating or releasing from something that holds-fast, connects, couples or entangles.

Engage refers to contacting, interlocking or meshing one or more items, mechanisms, objects, things, structures or the like. Engaging is exemplified in FIGS. 80A-80C and their descriptions.

Extending refers to spreading or stretching forth, to cause to reach (as in distance or scope), to cause to be of greater area or volume, to stretch out in distance, space, or time. Extending is exemplified in FIGS. 94A-94D and their descriptions.

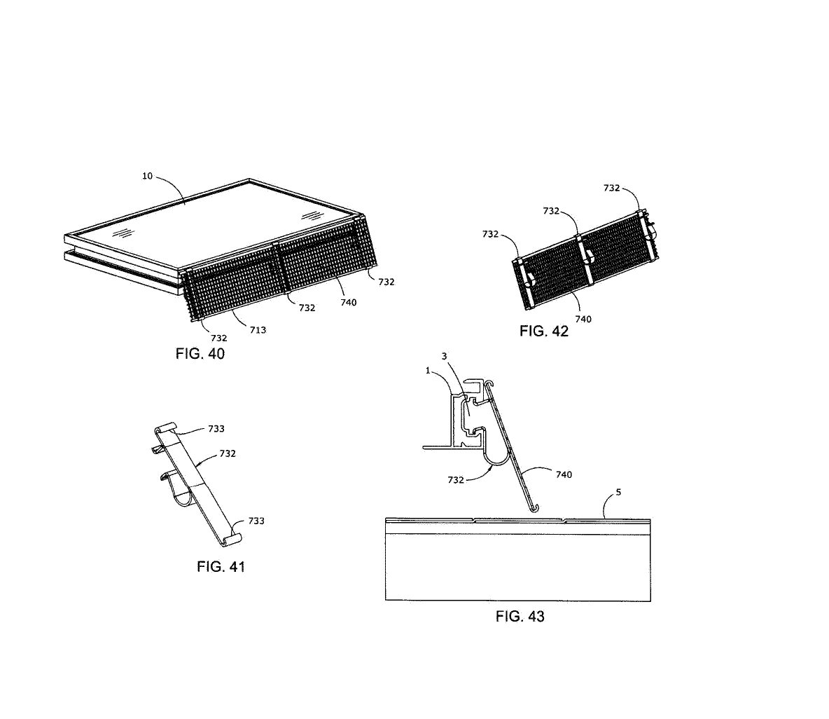

Flexible portion refers to a part, segment or portion of a device or feature that is capable of bending or deforming easily, such as made with a supple, pliable, pliant, or elastic material. For example, some skirts that have a flexible portion used to follow a contour of a support surface, such as a roof, are exemplified at screen 740 in FIG. 40, and its descriptions.

Following a curve of a roof tile refers to matching, mating or mimicking the uppers surface or contour of a roof tile. For a support surface, such as a roof that is undulating or curving such as a tile roof (for example, a clay roofing tile shaped like a longitudinal segment of a cylinder) the contour of each tile would be a half-circle, and the contour of the roof would be essentially shaped like a sine-curve (with a slightly different, half-circle, arc) in the direction normal to the roof incline. Thus to follow the curve of the plurality of roof tiles as normally mounted on a roof, the curve-following would have, or be deformed into, an essentially scalloped form. Some screens that follow a contour of an exemplar tile roof are exemplified at skirt 264 in FIG. 64A, and its descriptions.

Front edge refers to the forward-most, leading, termination, outside limit or furthest protruding from the center portion of an object, item, apparatus, combination, feature, area or surface. For example, a front edge of a PV array would normally include the most down-slope (for a sloped or slanted support surface) terminus of the PV module frame for the most down-slope PV module in a PV array. Some front edges of a PV array are exemplified at location F in FIG. 2, and its descriptions.

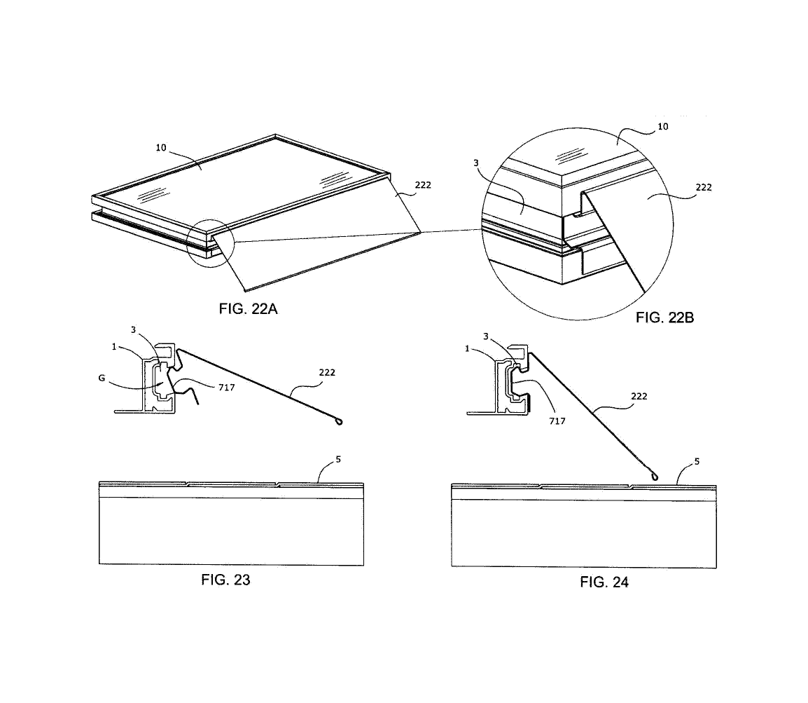

Groove refers to a long, narrow cut, rut, indentation, channel, furrow, gutter, slot or depression often used to guide motion or receive a corresponding ridge or tongue. Some grooves in the frame wall of a PV module are exemplified at Area G in FIG. 23, and its descriptions.

Height adjustable refers to change or adapt to bring items or components into a proper, desired or preferred relationship of a distance or elevation above a recognized level, such as the ground or a support surface. Some height adjustable devices are exemplified at Area H in FIG. 55, and its descriptions.

Inside portion or inner portion refers to, in regards to a frame discussed below, that portion of a frame not readily accessible from a position adjacent to said photovoltaic module, referring without limitation to that portion of the frame substantially beneath a photovoltaic laminate, excepting any groove on the outermost surface of the frame or portions of that groove which may appear beneath the laminate. An inside portion or inner portion is exemplified at 9098 in FIG. 90A.

Near refers to closely related or associated, in a close manner, within a short distance or interval in space or time, and/or closer of two or more items or positions. This is exemplified in FIGS. 94A and 94B and their descriptions.

Obscure refers to conceal or keep an area or object from being seen, or to make an object or area faintly perceptible, lack clear delineation or indistinct. Some screens that obscure the area beneath a PV module or a PV array are exemplified at Area 0 in FIG. 12, and its descriptions.

Opening refers to something that is open, as breach, aperture; an open width or span; an open space serving as a passage or gap; a breach or aperture; a vacant or unobstructed space, such as one that will serve as a passageway; and/or a gap. Openings are exemplified at features 8606A-8606L in FIGS. 86-88 and their descriptions.

Outside portion or outer portion refers to, in regards to a frame discussed below, (i) the surface of the frame that features a groove, as well as (ii) the groove itself and (iii) all of the surfaces of the groove. Alternatively and without limitation, inside portion or inner portion refers to that portion of a frame accessible from a position adjacent to said photovoltaic module. An inside portion or inner portion is exemplified at 9099 in FIG. 90A.

Outward refers to moving, directed, or turned toward the outside or away from a center; of, relating to, or directed towards the outside or exterior; of, located on, or moving toward the outside or exterior or the outside; and/or away from a central point.

Perforations refer to holes, piercings, penetrations or apertures passing through a wall or screen usually into or out of an area. Perforations may be in a pattern, such as rows or columns or other patterns. Some perforations in a skirt are exemplified at feature 79 in FIG. 18, and its descriptions.

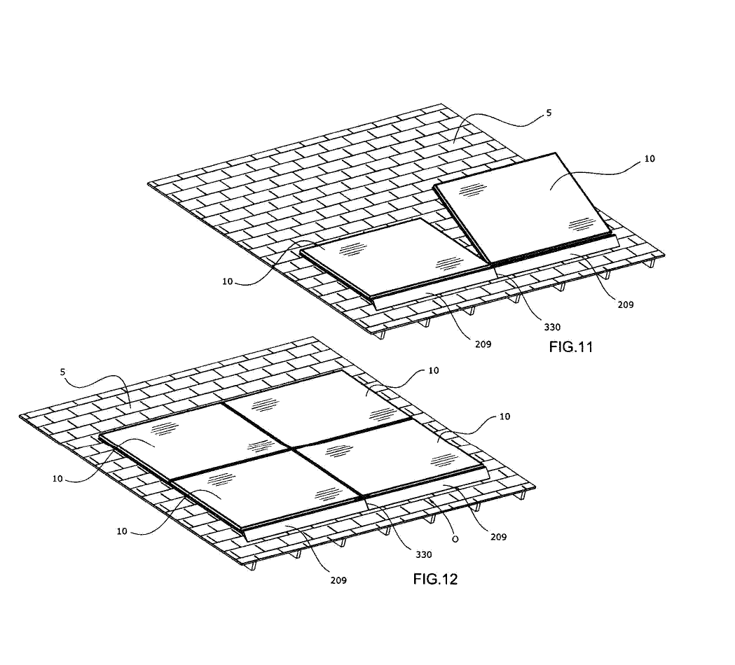

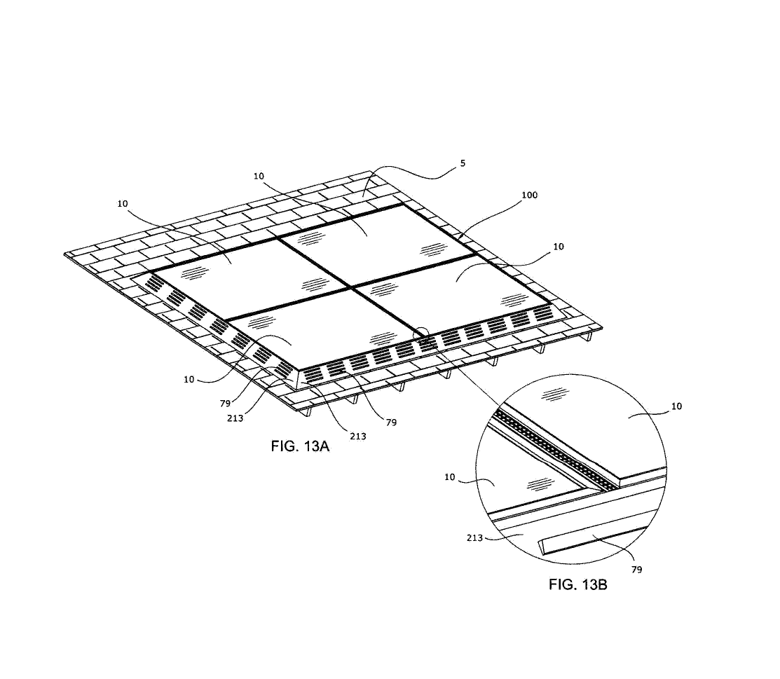

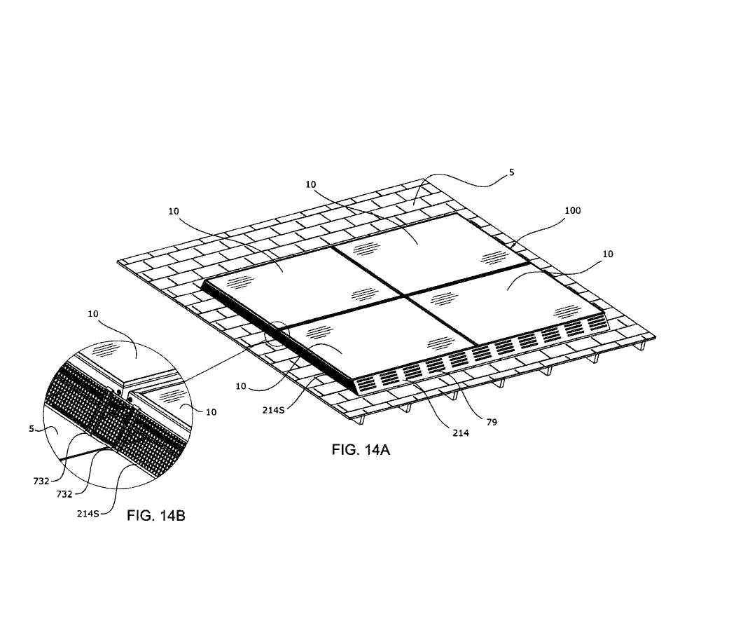

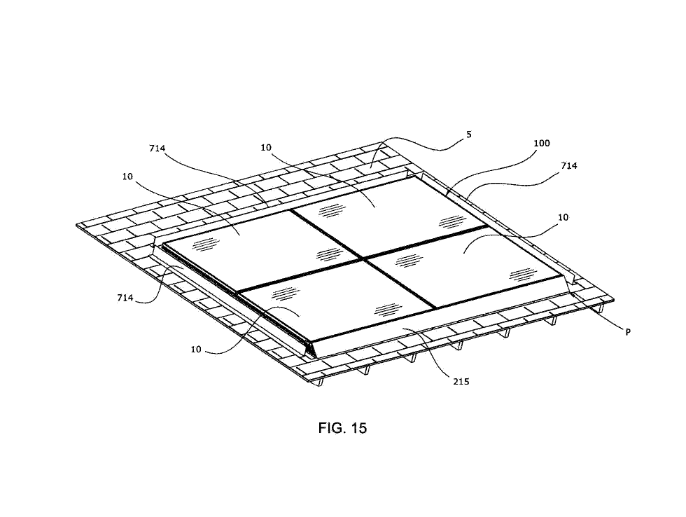

Perimeter refers to an essentially continuous line forming the boundary, periphery or circuit of a closed geometric figure; the outer limits of an area. An example perimeter of a PV array is exemplified at Area P in FIG. 15, and its descriptions.

PV array refers to a plurality of photovoltaic modules connected together often in a pattern of rows and columns with module sides placed close to or touching other modules. An example PV array is exemplified at array 100 in FIG. 1A, and its descriptions.

PV module refers to a photovoltaic module (sometimes referred to as a solar panel or photovoltaic panel) in a packaged interconnected assembly of solar cells, also known as photovoltaic cells. A plurality of PV modules are commonly used to form a larger photovoltaic system referred to as a PV array, to provide electricity for commercial, industrial and residential applications. An example PV module is exemplified at module 10 in FIG. 1A, and its descriptions.

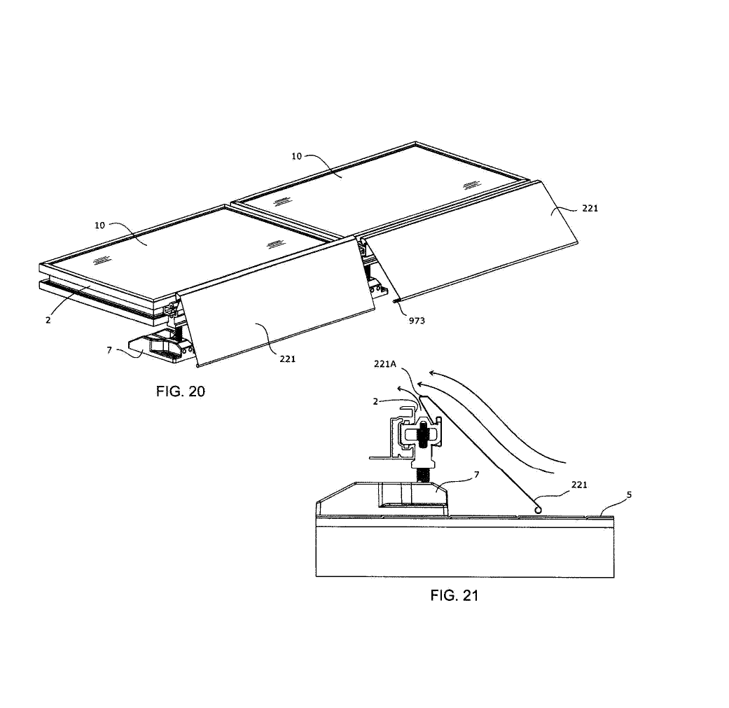

Rigidly couples refers to joining, linking, connecting or mating two or more objects or items together in a non-flexible manner that is difficult to bend or be forced out of shape. For example, two skirts may be rigidly coupled together, as exemplified at pin 973 in FIG. 20, and its descriptions.

Roof refers to a structure or protective covering that covers or forms the upper covering or top of a building. The upper surface of a roof is often used as a support surface for mounting, connecting or otherwise attaching a PV module or a PV array. For example, some roofs are exemplified at roof 5 in FIG. 1A, and its descriptions.

Roof tile refers to a manufactured piece of hard-wearing material such as ceramic, stone, metal, or even glass generally used for covering a roof There are many shapes of roof tile, including flat and shaped like a longitudinal segment of a cylinder. Some roof tiles are exemplified at tile 305 in FIG. 64A, and its descriptions.

Scalloped refers to an object having an edge or border marked with or shaped into a wavy pattern, for example in the form of semicircles; also referring to an ornamental edge made up of a series of curves or curved projections. Some scalloped edged skirts are exemplified at skirt 264 in FIG. 64A, and its descriptions.

Screen refers to a fixed or movable partition, cover, curtain or shield used to divide areas. A screen may be in the form of traditional sieve-type or other screen(s), hole(s), perforation(s), louver(s) or the like (which are herein more generally referred to as a “screen”, “screens” or “screen(s)”) and may be commonly used to partially or fully block a view past the screen or provide some rigidity while often permitting air (or other fluid) to flow through the screen. Some screens in a skirt are exemplified at screen 214S in FIG. 14B, and its descriptions. Some complementary screens in a skirt are exemplified at screen 370 in FIG. 62, and its descriptions.

Screen portion refers to a part or entirety of an item which is formed or embodies a screen. Some screen portions of a skirt are exemplified at screen 214S in FIG. 14B, and its descriptions.

Separate refers to forming or viewing an object as an individual, different, or distinct unit—apart or by itself; not joined or physically touching another object. An example of a separate coupling which may be used with a PV array skirt is exemplified at skirt insert 252 in FIG. 54, and its descriptions.

Skirt refers to an edging, molding or covering that may be fixed to the edge of a PV module to conceal or block the bottom area under a PV array when the PV array is mounted to a support surface. Some skirts are exemplified at skirt 202 in FIG. 2, and its descriptions.

Supporting refers to holding up or serving as a foundation or prop for; to bear the weight of, especially from below; to hold in position so as to keep from falling, sinking, or slipping; the act of bearing the weight of or strengthening; and/or capable of bearing a structural load.

Support surface refers to a structure, such as a roof, table or the ground which may provide a base for securing PV modules to form a PV array. Some support surfaces are exemplified at roof 5 in FIG. 1A, and its descriptions.

Spread of flame refers to extending, distributing or dispersing over an area so as to extend the surface area, length or width of a fire or hot body of ignited gases, vapor or plasma.

Referring now to the figures, and particularly to FIGS. 1A, 1B and 1C, there is shown a PV array, such as array 100 comprised of photovoltaic (PV) modules, such as modules 10 mounted on a support surface such as a roof 5. The modules 10 within this array 100 contain photovoltaic laminates, such as laminates 1 that are supported by appropriate support structures, such as frames 2, which may be made of aluminum or other material as known in the art, which may contain a groove, such as groove 3 located on an outside surface 4 of frame 2. As described in prior documents, groove 3 allows for the interlocking and direct attachment of PV modules to roof 5 or other support structure by use of couplings such as interlocks 6 and may also include structures for attachment to roof 5, as by a foot (feet) 7 that connect to groove 3. In other embodiments PV modules 10 comprise a PV frame 2 without any groove 3. FIG. 1B is a detail view of the area in the leftmost circle of FIG. 1A, which shows a closer view of foot 7. FIG. 1C is a detail view of the area in the rightmost circle of FIG. 1A, which shows a closer view of interlock 6.

FIG. 2 shows a skirt positioned at the bottom edge or front edge of array 100, such as array skirt 202 installed on the front edge, shown at F, of array 100. Array skirt 202 may provide many benefits including, but not limited to, improved aesthetics, improved fire safety, and improved structural performance. Array skirt 202 may partially or fully obscure the air gap and mounting hardware located beneath a PV array, such as array 100.

FIGS. 3A, 3B, 3C and 3D show a profile view of an embodiment of a skirt, such as extrusion 203 with a groove 300 located on the interior surface, such as surface 500. The profile such a skirt design may allow for a pivot-fit connection of skirt 203 to a coupling, such as coupling 8, which is shown as located above a mounting foot, such as foot 7 which may have a base portion, such as base 9. Coupling 8 may also allow for a pivot-fit connection for a module 10 having a frame 2 containing a groove 3 on outside surface 4. A pivot-fit connection between the components and grooves 3 and 300 may be achieved by presenting male portions 8A and 8B of coupling 8 to female grooves. The grooves may then seat at least partially over the male portions 8A and 8B and then rotate down until the angle of the groove substantially aligns with the axis of the male portions 8A and 8B. To complete the pivot-fit connection, the PV module 10 or skirt 203 is simply pivoted down to its final angular orientation in the PV array. This final rotation causes bearing portions in the groove to bear against the male portions of the coupling 8 to restrain the PV module or skirt against upward or downward movement. The coupling may still allow for adjustment of the PV module position in the plane of the PV array to account for tolerance variations.

In order to further limit or inhibit the potential upward rotation of a skirt 203 on coupling 8 an anti-rotation component, such as component 11 may be attached to the coupling 8, such as by insertion into an aperture 12 formed into the top surface of coupling 8. When properly installed into aperture 12, component 11 will restrict or act to prevent or limit upward rotation of the skirt 203. Upward rotation is restricted by placing a surface 13 of the anti-rotation component 11 in direct contact with vertical surface 500 of skirt 203. Skirt 203 may be connected to coupling 8 before or after module 10 is installed and may be easily removed from array 100 by removing anti-rotation component 11 from aperture 12, thus allowing the upward rotation required for skirt removal.

FIGS. 4A and 4B show perspective views of the inside or up-roof side of two skirts 204 that have been linked together via an interlock 6 containing couplings 8. Interlock 6 may optionally further comprise the base portion 9 of mounting feet 7 as shown here. In some embodiments base portion 9 is eliminated. Anti-rotation component 11 may be inserted into apertures 13 in order to create a wedged fit that may resist rotational movement of skirt 20.

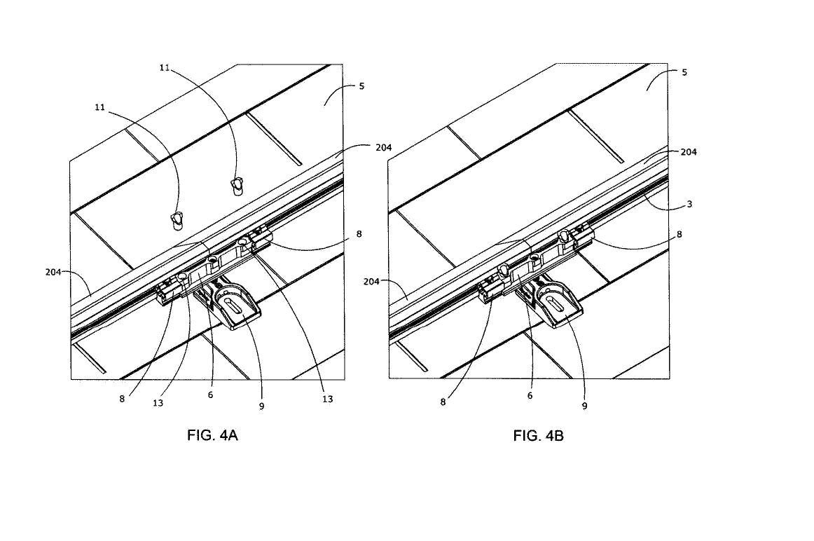

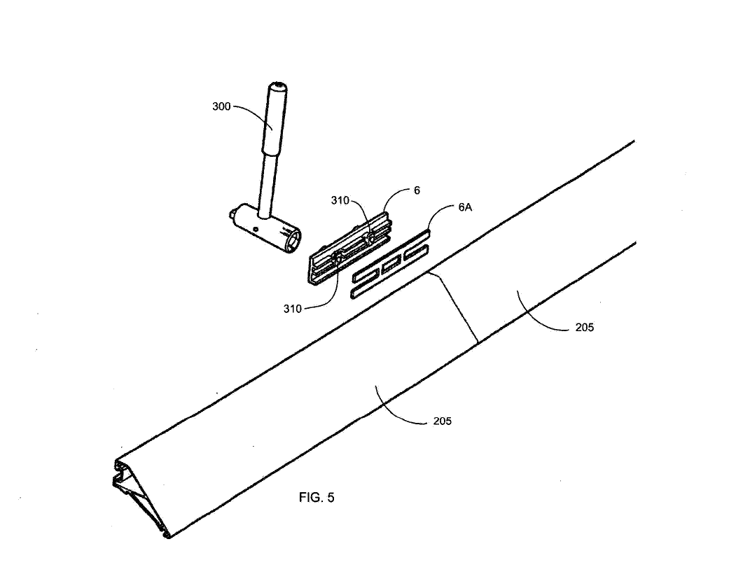

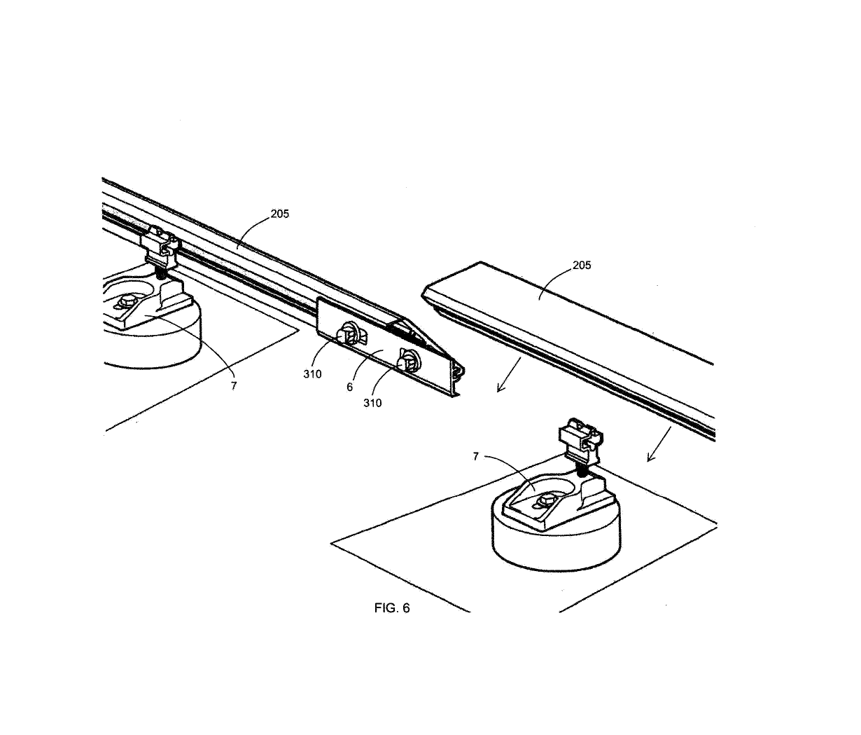

FIGS. 5-8 show a sequence of installation steps for an embodiment of skirt 205. FIG. 5 shows two skirts 205 placed end-to-end and ready to be interlocked together with interlock 6. Spacer plate 6A may be positioned between interlock 6 and skirts 205 to prevent skirt from sagging. Tool 300 may be utilized to rotate parallel couplings 310 of interlock 6 to connect interlock 6 to skirts 205. As shown in FIG. 6, skirts 205 may be connected to feet 7 and interlocked to additional skirts 205 along a perimeter of PV array 100. As shown in FIG. 7, anti-rotation components 11 may be inserted into feet 7 to further secure skirts 205 to feet 7. FIG. 8 shows the completed PV array 100 comprising PV modules 10, skirts 205, interlock 6, and feet 7 (not shown, appearing in FIG. 7). As can be seen here, interlock 6 may couple two PV modules 10 and two skirts 205 together. This arrangement may provide better structural performance than a skirt system that for example only provides a connection point from skirt to array at the mounting foot. Such a system could sag under heavy load at the four (4) corners point where two PV modules 10 and two skirts 205 meet. In some embodiments interlock 6 may further provide a ground bond connection between modules 10 and skirts 205. In other embodiments interlock 6 may provide a ground bond connection between modules 10 and skirts 205 as well as a ground connection from one skirt 205 to the adjacent skirt 205.

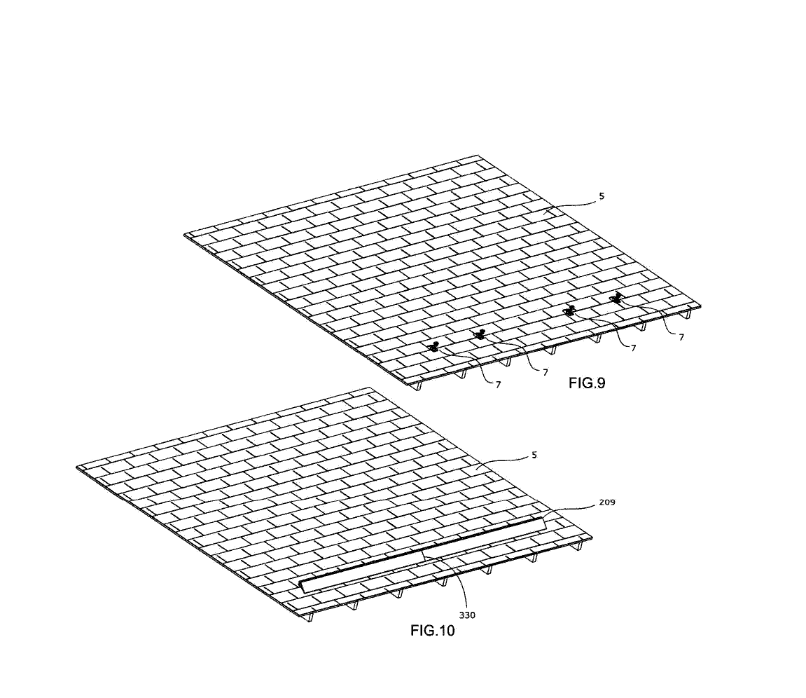

In addition to providing aesthetic and other enhancements, another benefit of disclosed array skirts may be the ability for use as a jig or tool for controlling the location and alignment of modules positioned in the first installed row of an array. The method of installation for using a skirt 209 as a jig is shown in FIGS. 9-12. The use of skirt 209 for alignment purposes may provide a template for module installation in discrete and repeatable locations. In one embodiment skirt 209 is provided with a length that is the same as the length of PV module 10 plus a small amount to create a small gap between adjacent modules 10. As shown in FIG. 9, feet 7 may be installed on a roof first. Skirts 209 may then be interlocked together, as described above, and connected to feet 7 (as shown in FIG. 10). PV modules 10 may then be attached to skirts 209, using seam 330 between skirts 209 as a guide to determine where to place the modules. Subsequent rows of PV modules 10 may be installed above the first row in the usual fashion.

One skilled in the art will recognize that skirts 209 (and other skirt embodiments disclosed in this specification), when installed in this way, may provide a simple way to determine the layout of PV array 100 on a roof prior to installing PV modules 10. It would also be clear that PV array 100 may contain various numbers of rows and columns of modules 10 and that the orientation of the long dimension of a module 10 may be running either up and down the roof or side to side along the roof Non-rectangular arrays 100 may also have skirts 209 along various portions of the perimeter.

By enabling this method of installation, both the time and number of people required to install modules 10 in the first row of an array 100 may be substantially reduced. Further advantages of using a skirt 209 as a jig may include enabling a method for installers to install the first row of modules 10 in an array 100 from a location that is a safe distance from a rooftop or other surface's edge. An additional advantage may be the ability to mount modules all the way to a rooftop or other surface's edge without the need for installers to be on ladders and/or scaffolding. This benefit may result from the provision of interlock 6 (not shown, appearing in FIG. 8B) which may couple skirts 209 together in addition to coupling modules 10 together via a pivot-fit, drop-in type of mounting as described earlier. The combination of simplified first row module installation and increased installer safety may result in reduced overall installation time and therefore reduce total system installation cost.

Array skirts may also be automatically bonded (for electrical grounding purposes) to PV module frame 2 through the use of interlocks 6 (not shown, appearing in FIG. 8B) comprising couplings with grounding features that provide a ground bond path between skirts 209 (and other skirt embodiments disclosed in this specification) and PV module frame groove features 3. The bonding in this case is automatic since mechanical connection of interlock 6 (not shown, appearing in FIG. 8B) to skirt 209 automatically cuts a ground path in the material, possibly eliminating the need to run separate grounding wires to the devices. Thus, the automatic grounding feature skirt 209 enables may further reduce total system installation time, as well as material costs.

FIG. 13A shows the same array depicted in FIG. 1 except further comprising array skirt 213 installed on all four sides of the array. FIG. 13B is a detail view area in circle of FIG. 13A. In order to allow for enhanced power output of the modules 10 within array 100, skirt 213 may comprise louvers 79 to permit dissipation of heat from beneath the array. These louvers 79 may be added to a skirt 213 through common stamping or other low cost manufacturing methods. Also disclosed in FIGS. 13A and 13B is a snap-in module gap screen 712 that may prevent entry of organic debris, rodents, burning embers, etc. As further disclosed below, this screen may be installed using module gap spring clips containing male features or tabs that interface with the frame groove 3 (not shown, appearing in FIG. 4B) located on adjacent module frames in order to secure module gap screen 712 in place.

FIG. 14A shows a PV array 100 with skirt 214 mounted on the front and side screens 214S mounted on the remaining sides of the array. FIG. 14B is a detail view area in circle of FIG. 14A The side screens 214S may mount to the frame groove 3 using fasteners, spring clips (shown in FIG. 14B detail view and further disclosed below), wedges, camming devices or other components containing geometrically compatible male features. In other embodiments side screens 214S mount to the side or top of frames 2. Side screens 214S may comprise a perforated screen portion as shown or louvers or variously sized and space holes.

FIG. 15 shows a PV array 100 with skirt 215 mounted on the front side and fire barrier walls 714 installed directly to roof surface 5 on the other sides of the array. One of skill in the art would recognize that fire barrier walls 714 may also be mounted to other surface types. These fire barrier walls 714 may be affixed to a roof surface 5 using fasteners, adhesives, etc. and may be placed at an optimal distance from an array 100 to prevent flames from entering the air gap beneath. The fire barrier walls 714 may also be used in conjunction with module gap screens 712 and array side screens 713 in order for organic debris and burning embers to be prevented from entering.

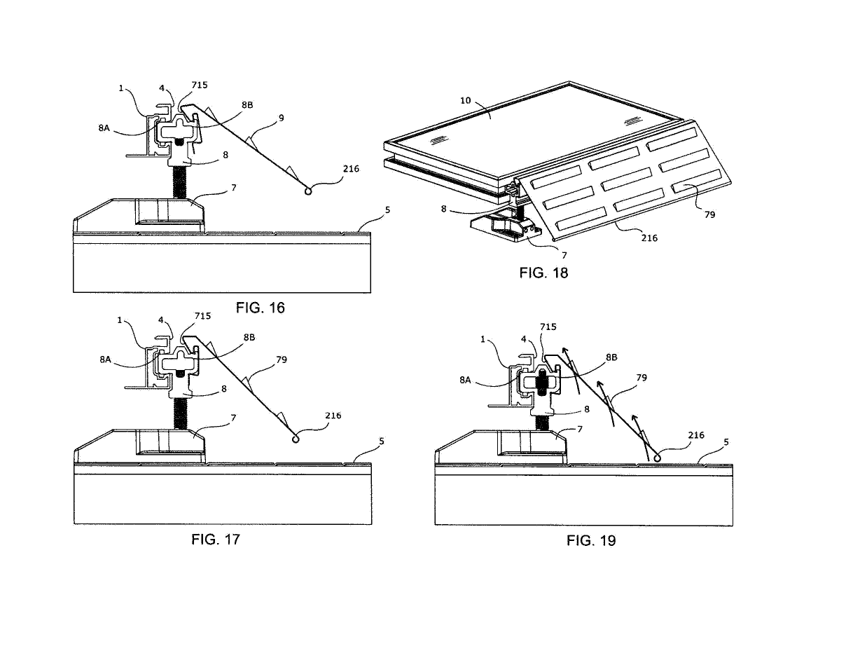

FIGS. 16-19 show an embodiment of skirt 216 with louvers 79. Skirt 216 may be manufactured from bent metal and may snap onto coupling 8 male features 8A or 8B via a spring clip portion 350. As shown in the profile view of FIG. 16, the shape of skirt 216 and louver features 79 is such that a traveling open flame coming into contact with the skirt outside surface 711 may roll over the skirt and an array 100 of modules 10 while not allowing flames into the air gap beneath the array. The airflow dynamics caused by the flame may create negative pressure that draws air out through louvers making it even more difficult for flames to spread beneath array 100. Skirt 216 may also effectively prevent organic debris from accumulating beneath array 100 by substantially reducing the accessible air gap. Embodiments of feet 7 may allow for vertical height adjustment and connect directly to PV modules 10 therefore allowing for adjustment of the height of skirt 216 above a surface such as roof 5, thus ensuring that the proximity of the bottom of skirt 216 to a surface may be optimally positioned for preventing debris from entering the underlying air gap. The gap provided between surface 715 of skirt 216 and the outside frame surface 4 may be sized in order to enable adequate room for installing groove mounted wire clips, device mounting brackets, and other items.

As shown in FIGS. 20-21, some embodiments contemplate that skirt 221 further comprises pin 973 for rigidly coupling two skirts 221 together. Pin 973 may be a dowel pin, threaded fastener, press-fit pin or splice, and other device for rigidly coupling two skirts 221 together. FIG. 21 shows how skirt 221 may further comprise top surface 221A that is purposely raised above the top plane of array 100 such that air moving over skirt 221 may cause a Venturi effect that creates an updraft at the gap located between skirt 221 and PV module frame 2. This induced updraft may effectively enhance heat removal from beneath an array 100 and potentially reduce or eliminate the need for louvers or other means of ventilation while still providing the fire protection benefits enabled by a skirt, barrier wall or other form of block.

FIGS. 22-24 show an embodiment of a low cost single piece skirt 222 that may be attached directly to groove 3 located on the outside surface 4 of module frames 2. Male feature 717 of skirt 222 is geometrically compatible with the frame groove 3 and may rapidly install by a spring clip type connection that deforms the profile shape of the male feature 717 resulting in spring force being applied to the inside surfaces of the groove 3.

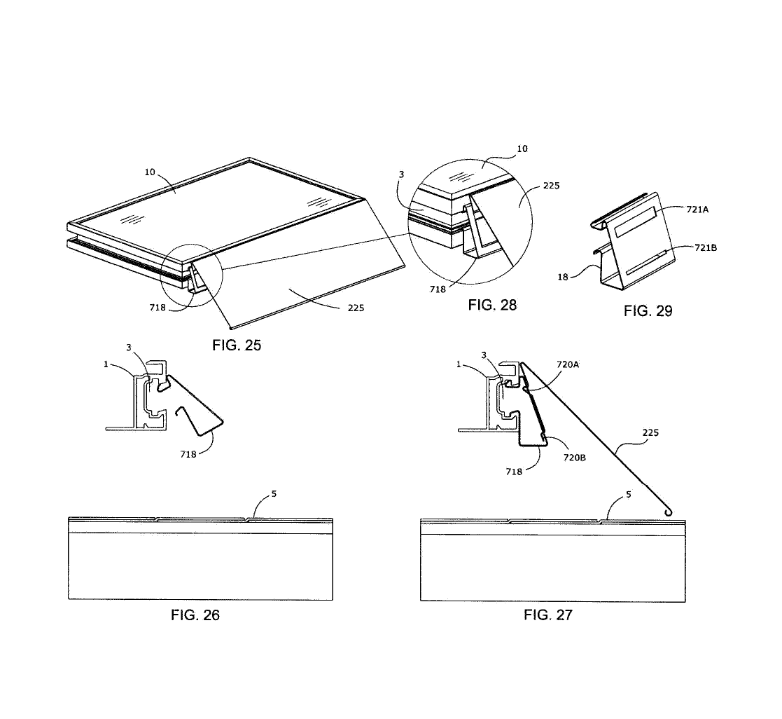

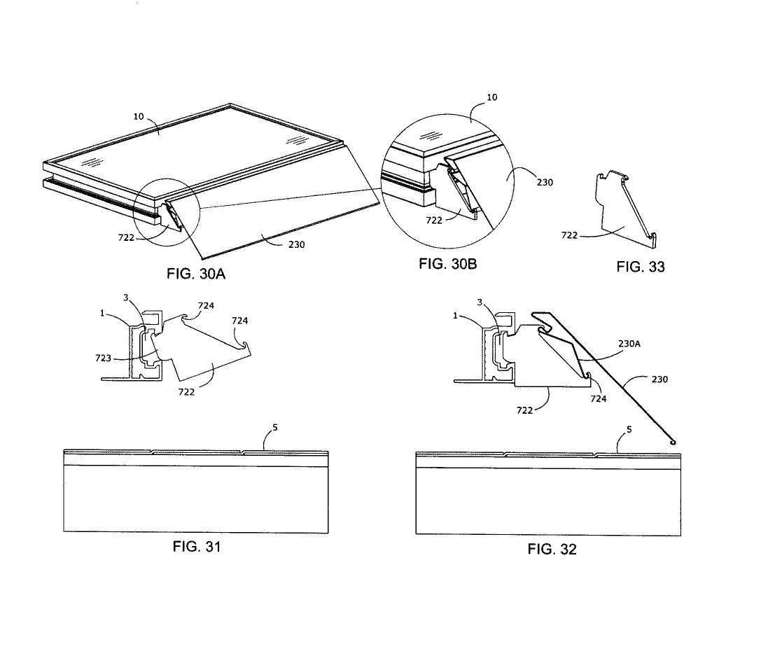

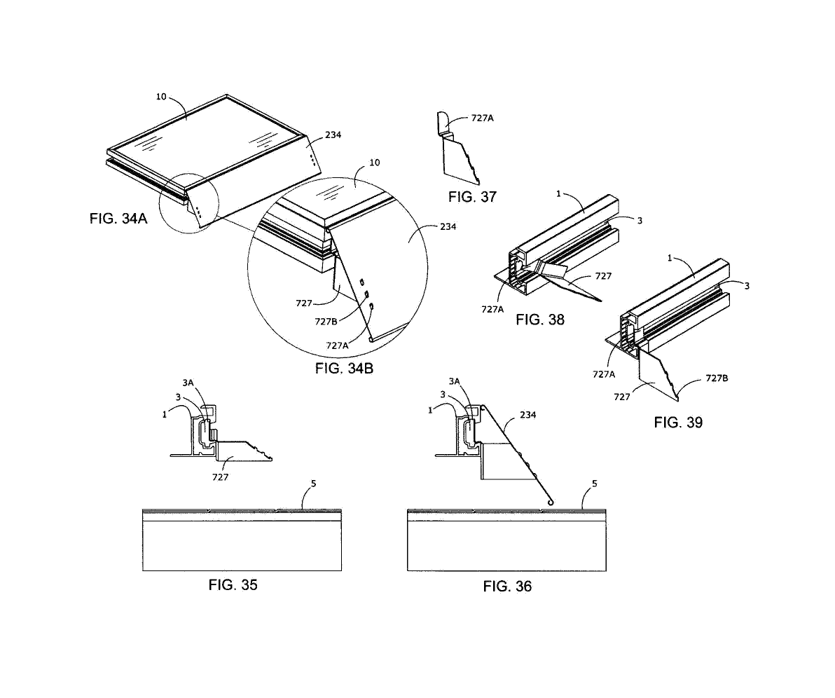

FIGS. 25-39 show alternate methods of attaching further embodiments of array skirts to the frame groove 3 by using various embodiments of frame groove engagement clips spaced at appropriate interval distances along the length of frame 2.

FIGS. 25-29 show a groove compatible spring clip 718 that may be inserted into frame groove 3 at appropriate interval distances along module frame 2. A low cost and easy to manufacture skirt 225 may then be installed to the spring clips 718 by inserting tabs 720A and 720B into slot features 721A and 721B.

FIGS. 30-33 show frame engagement clip 722 that may contain a ridged male feature 723 that may elastically deform frame groove 3 when inserted thus resulting in a spring induced clamping force that secures the clip in place. Rounded end features 724 located on clip 722 allow for compatible skirt insert section 230 to be attached before or after the clip 722 has been installed by elastically deforming spring section 230A of skirt 230.

FIGS. 34-39 show an additional embodiment of a frame groove compatible clip 727 in which male engagement feature 727A of a rotatable groove attachment clip 727 may be inserted laterally into the frame groove 3 at an approximate angle as shown. Once positioned within the groove at a desired location along the frame, the clip may then be rotated until substantially perpendicular with the top plane of module 10 to force engagement of male feature 727A with the slot 3A located with the female groove 3. Male feature upturned portions 727B of clip 727 may then be used to attach a compatible skirt section 234 using mounting slots 234A.

FIGS. 40-43 shows an additional frame groove compatible spring clip 732 for mounting screens 740 to the sides of a module 10 or array 100. Spring clip arm portions 733 may be used for affixing screen sections 740 once the spring clips are installed in appropriate locations in groove 3 along frame 2. Alternatively, screen sections 740 may be affixed to the spring clip arm portions 733 prior to installation and mounted to the frame groove 3 as a preconfigured assembly.

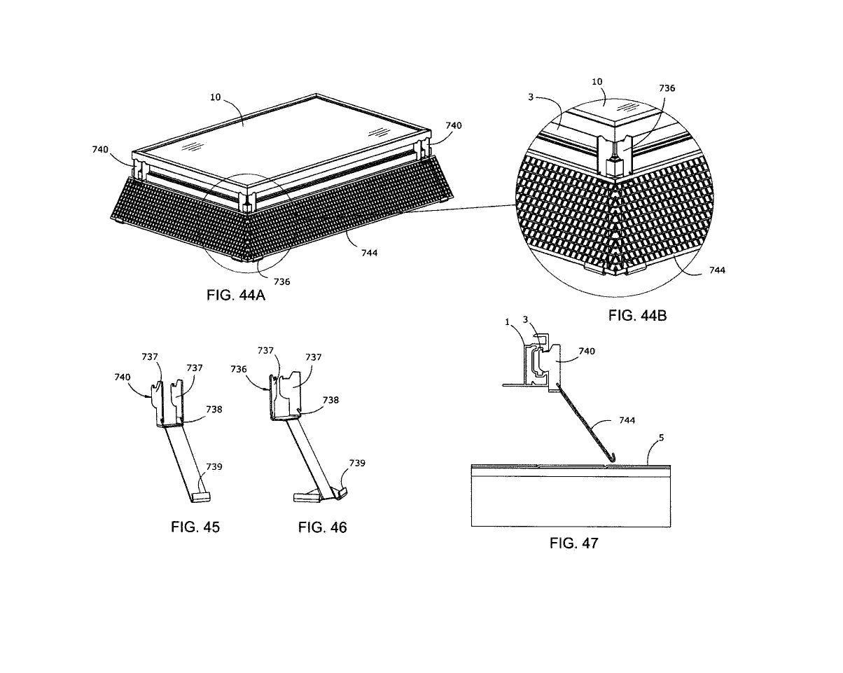

FIGS. 44-47 show frame engagement clips 736 and 740 that may be inserted into the frame groove 3 at the corners and sides of modules 10, respectively. Both corner 736 and side 740 frame engagement clips may be used to install side screens 744 or various embodiments of skirts using capture features 738 and 739.

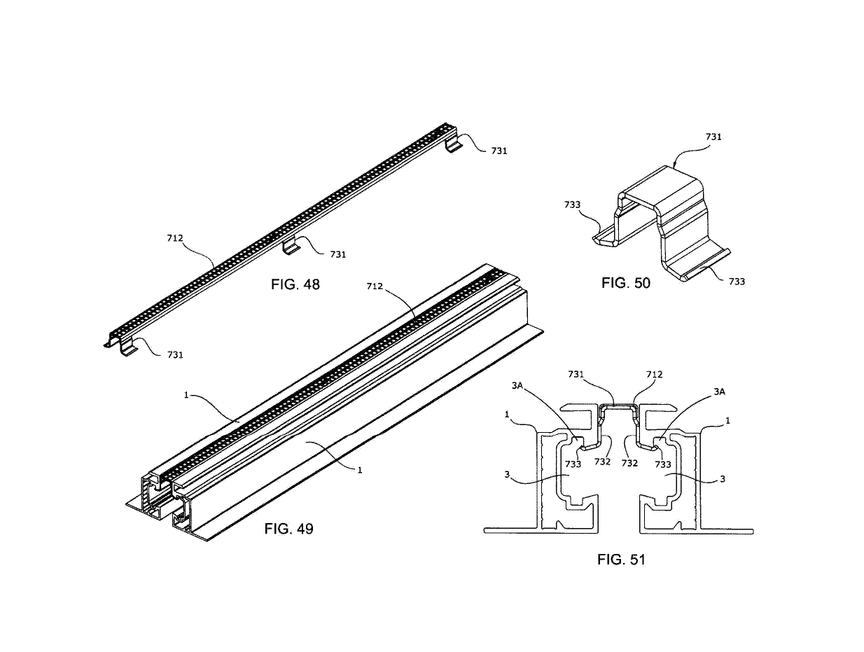

FIGS. 48-51 show an embodiment of a module gap spring clip 731 that may be used to install top screens 712 to protect against entry of organic material, rodents, burning embers, etc. at the gap between adjacent module frames. Spring tabs 732 insert into the frame groove 3 and contain hooked tips 733 that positively engage with upper slot 3A of the frame groove 3. The spring force enabled by the elastic deformation of the tabs during installation may assist in securing the screen against forces imposed by nature such as snow, ice or wind. Additional embodiments of the spring clip design may contain shaped features at the top end of the clip that prevent over insertion during installation into the module gap and may also further aid in resisting down forces imposed due to snow, ice and wind.

FIGS. 52-55 show an extrusion span jig 800 for aligning modules 10 and enabling rapid installation. Extrusion span jig 800 may contain features 734 that allow for a low cost skirt section 252 to be installed at the front of the array. Extrusion span jig 800 may contain a groove 301 that may be installed onto geometrically compatible male features 8A or 8B located on the coupling portion 8 of one or more of feet 7.

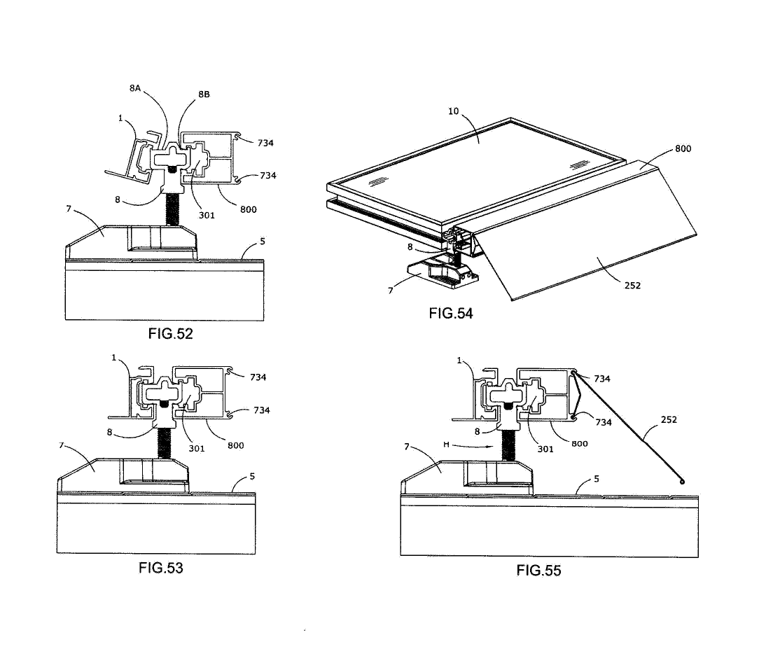

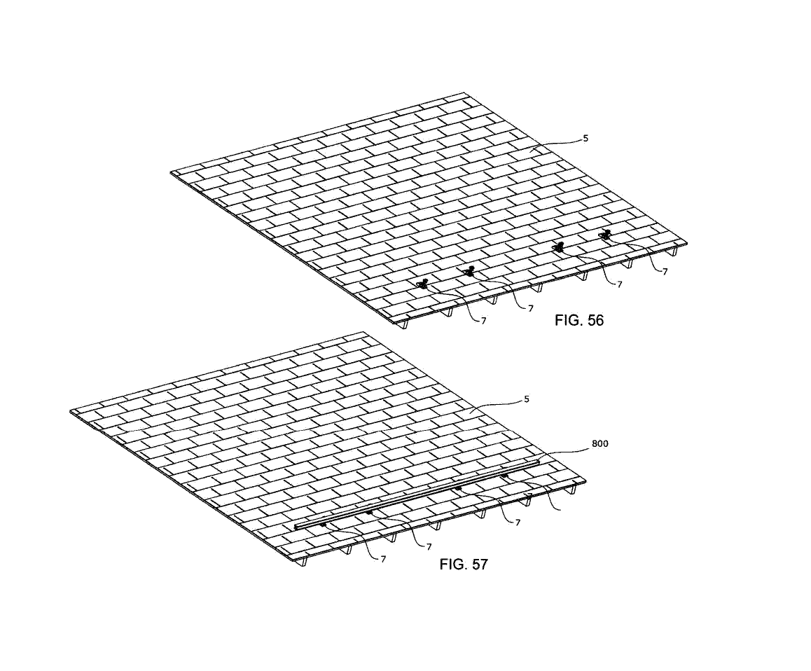

FIGS. 56-57 show a rooftop surface 5 with height adjustable mounting feet 7 installed in predetermined locations and an extrusion span jig 800 installed onto the mounting feet 7.

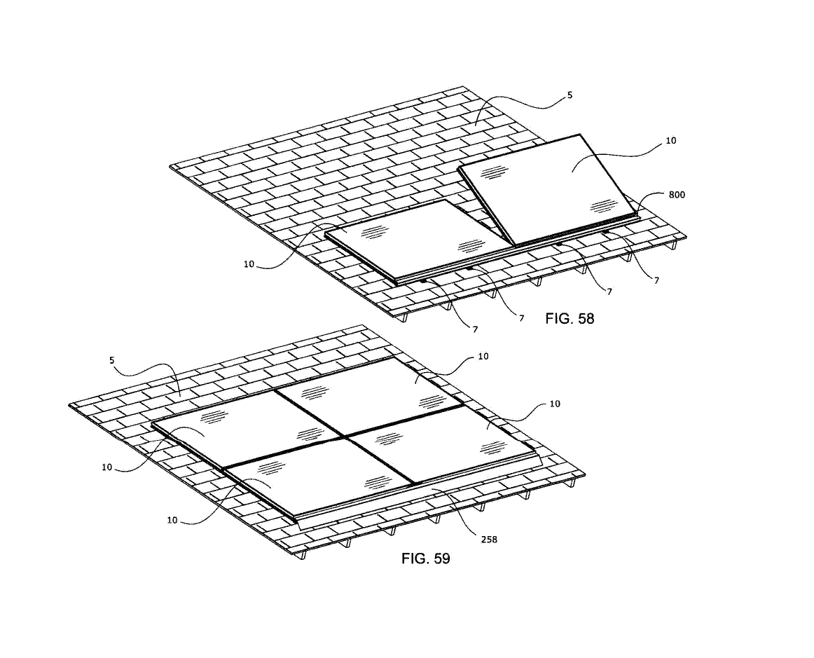

FIGS. 58-59 show a first row of modules 10 installed on the mounting feet 7 aligned with extrusion span jig 800 and an installed array 100 with the skirt section 258 attached to the extrusion span jig 800.

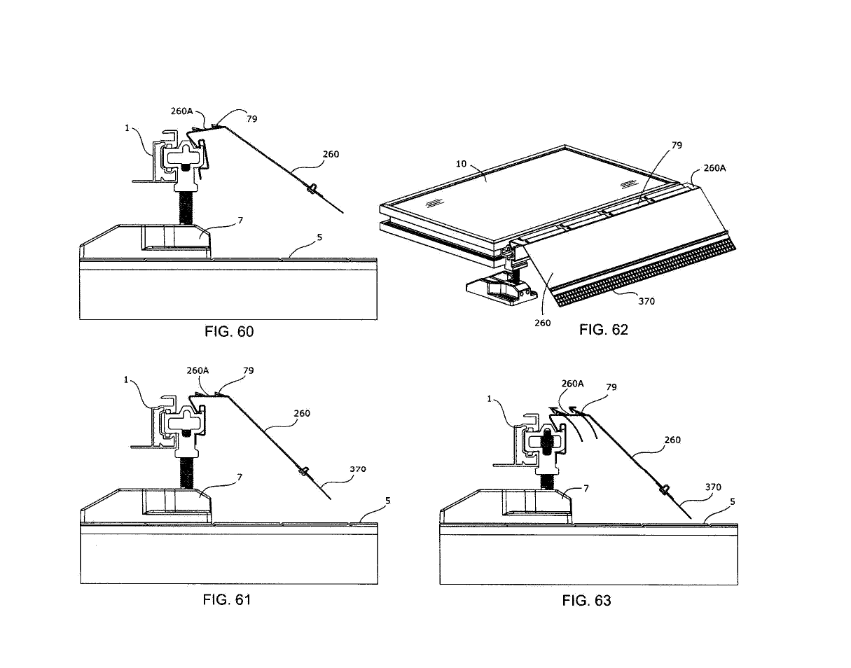

FIGS. 60-63 show skirt embodiment 1260 comprising louvers 79 located along the top of portion 260A of skirt 260. A separate flexible screen material 370 may be attached to the bottom of the skirt using common fasteners.

In embodiments skirt and screen elements disclosed above may be constructed of flexible materials that may conform to surface variations on the roof, thus providing an effective barrier.

FIG. 64A shows a skirt embodiment 264 comprising a scalloped lower portion that conforms to a shape of a curved tile roof 305. FIG. 64B is a detail view of area in circle of FIG. 64A.

FIG. 65 disclose the manner in which the wedging fit of an anti-rotation component 11 may prevent interlock 6 from disengaging from within a module frame groove 3 due to rotation caused by downward module deflection created by heavy loading due to imposed forces from snow, ice or wind. This disengagement may once again be prevented by forcing a surface 13 of the anti-rotation component 11 in direct contact with a surface of a module frame 15.

FIG. 66 shows an accessory component assembly 600 that may be used to mount electrical boxes 500 of various types to groove 3. As FIG. 66 shows, anti-rotation components 11 may also be inserted into apertures 412 located within the accessory component assembly 600 in order to prevent rotational movement of the assembly after it has been installed.

The prevention of rotational and translational movement of novel photovoltaic module mounting system components, tools and accessories through the use of the anti-rotation component 11, may enable enhanced safety and cost savings for various groove mounted components by preventing their accidental removal during installation or during regular O&M. In addition, the use of the anti-rotation components 1 may result in increased useful lifetime of various frame groove mounted products and photovoltaic modules by reducing wind induced vibration, increasing snow load capabilities for modules and preventing accidental removal and breakage of components.

Anti-rotation component 11 may be held within a hole or slot via a press-fit action, a tooth and barb connection, screw threads, other typical mechanical connections, or simply by gravity. In one aspect anti-rotation component is novel because the direction of insertion may be opposing the rotational force that it is resisting. For example, skirt 203 as shown in FIG. 3 must rotate counterclockwise to be removed, thereby imparting an approximately horizontal force on anti-rotation component 11. Yet anti-rotation component 11 is inserted in a mostly vertical direction as shown by the dashed line. Thus, the counterclockwise rotational force does not tend to push the anti-rotation component 11 back out, thereby allowing anti-rotation component to include a method of retention that allows easy installation by hand or lightweight tools.

Spring Bracket [T Lock]

Various embodiments and variants of an attachment device for Photovoltaic (PV) module connection to other PV modules and/or associated devices has been disclosed and shown in U.S. Provisional Patent Application 61/698,292 entitled “Module Attachment System & Module Support System” filed approximately Sep. 7, 2012; as well as U.S. patent application Ser. No. 13/408,846 entitled: “Pivot-Fit Frame, System and Method for Photovoltaic Modules”, filed approximately Feb. 22, 2012; each of which is incorporated by reference herein in its entirety. Other ancillary, including otherwise related or associated apparatus(es), system(s) and method(s) regarding embodiments of a wire clip, tile hook, skirt and other components have similarly been disclosed by applications of at least one of the named inventors hereto.

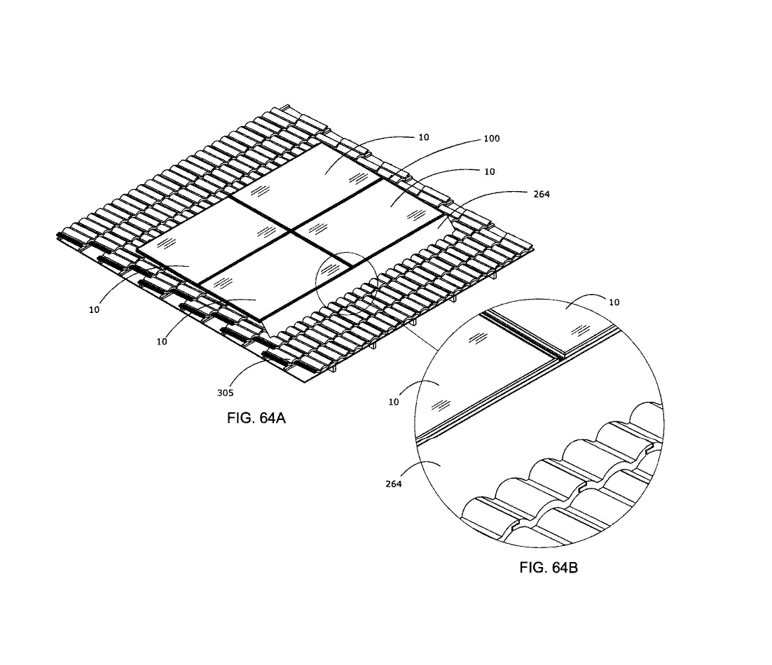

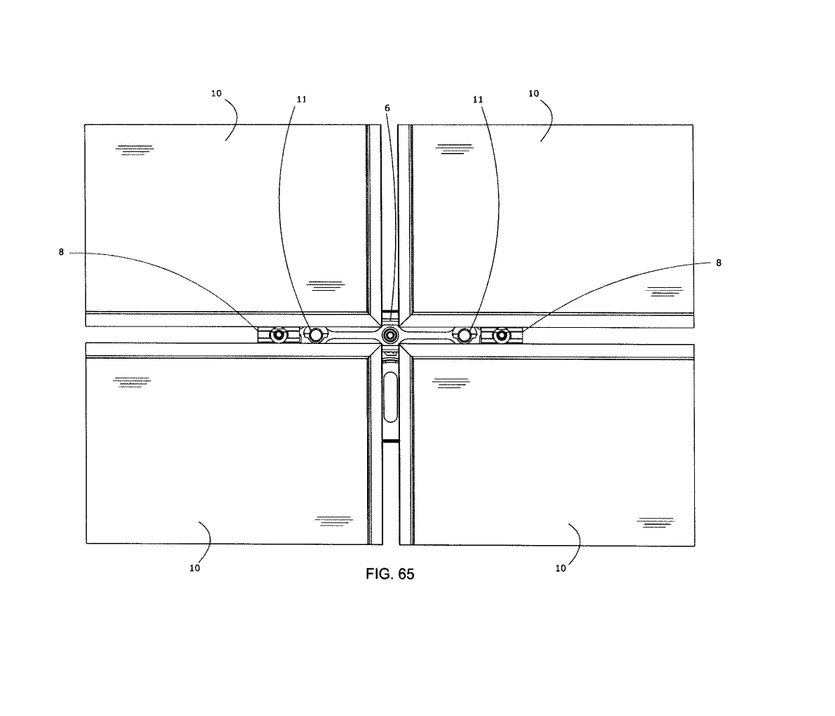

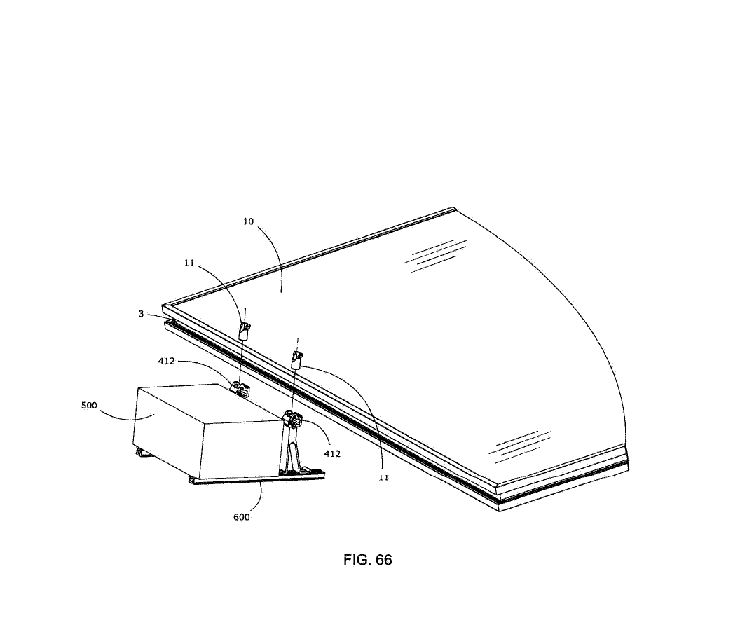

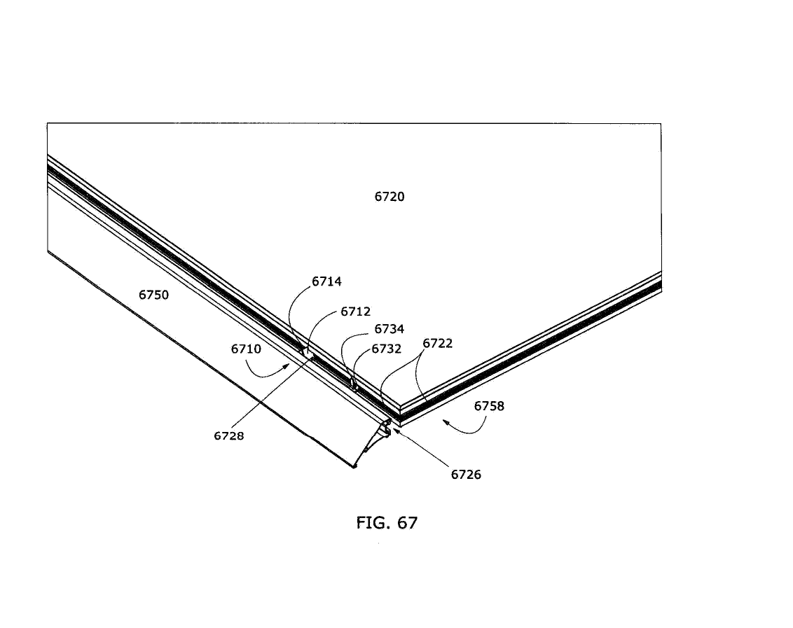

Referring now to an embodiment, particularly to FIGS. 67-72, wherein like numerals refer to like structures, a bracket, spring clip, “dream clip”, lock, T-lock, or spring arm device is shown, such as spring bracket 6710. FIGS. 67-72 show various embodiments of spring brackets from various perspective views, both independently and in combination with other devices, as further disclosed below. The term “bracket” generally refers to a simple structure with an elongate structure, sometimes in the general shape of an L or an I or a C, and frequently comprising a plate or sheet-type construction with one dimension typically thinner than the others in a given plate-like portion of the object. A bracket is often an overhanging member that projects from a structure (such as a portion of a wall or frame) and may be designed to support a load with a vertical component, such as a skirt, wire hanger, conduit, or the like. A bracket may also refer to a fixture projecting from a wall, column, frame, or the like which may be used for holding, securing, positioning or supporting another object. A bracket may also include or embody an arm. The term “arm” generally refers to a relatively narrow device, item, feature or portion of an item that extends, branches or juts-out from a mass or other part; also a slender part of a structure, machine, instrument or apparatus that projects from a main part, axis, pivot or fulcrum.

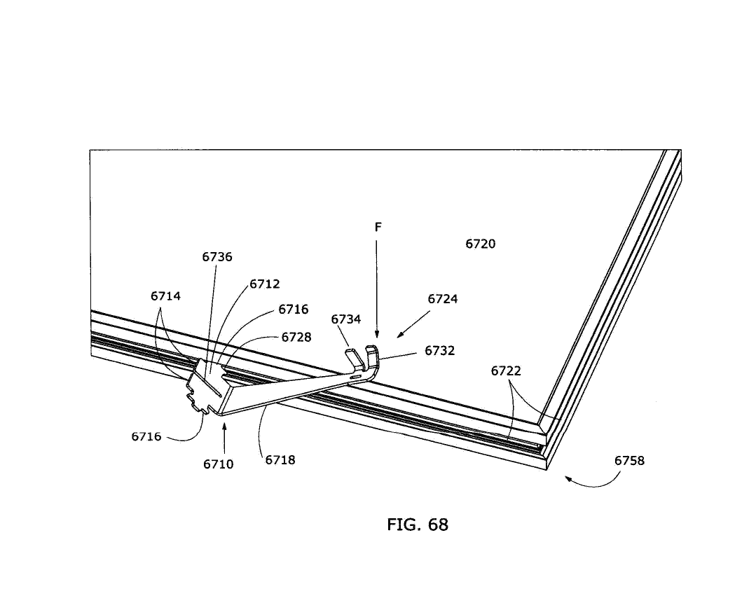

As shown, especially in FIGS. 67-68, a suitable spring bracket, such as spring bracket 6710, may be partially inserted into, and may lock into, a groove or channel, such as groove 6722 located on one or more portions, such as the outer facing sides of the periphery of a PV module, such as PV module 6720. In general, a channel refers to a device, item, feature or portion of an item that may have or embody a long, narrow cut, rut, indentation, channel, female portion, trench, furrow, gutter, slot or depression often used to guide motion or receive a corresponding male portion, ridge or tongue. Spring bracket 6710 may act as a connector between two PV modules, or between a PV module and one or more ancillary device(s) or structures, such as a wire clip, tile hook, skirt, and/or other components as may be further disclosed herein, or otherwise as would be understood by one of skill in the art. The term “connector” refers to an object, item, mechanism, apparatus, combination, feature, link or the like that links, joins, unites or fastens two or more things together. The term connector may also include a device, object, item, mechanism, apparatus, combination, feature, link or the like for keeping two parts of an electric or electronic circuit in contact. Spring bracket 6710 (or other embodiments of a spring bracket) may act as a coupling between two PV modules, and/or between a PV module and one or more ancillary device(s) or structures, such as a wire clip, tile hook, skirt, and/or other components as may be further disclosed herein, or otherwise as would be understood by one of skill in the art. The term “couple” refers to joining, linking, connecting or mating two or more objects or items, mechanisms, objects, things, structures or the like together and the term “coupling” refers to an object, item, mechanism, apparatus, combination, feature, link or the like that couples, joins, links, mates or connects two things together.

It can also be noted that spring bracket 6710 may engage groove 6722, where the term “engage” refers to connecting, coupling, fixing, hitching, linking, interlocking or meshing one or more items, mechanisms, objects, things, structures or the like and “disengage” refers to detaching, uncoupling, unfixing, unhitching, freeing, loosening, extricating, separating or releasing from something that holds-fast, connects, couples links, hitches, joins, or the like.

Referring again to FIGS. 67-68, wherein like numerals refer to like structures, spring bracket 6710 presents an apparatus, system, and method for adapting a component to engage a groove 6722 associated with a PV module 6720. One or more spring brackets 6710 (one shown) may be used to connect or couple a PV module with one or more other PV modules and/or with one or more items or combinations of other ancillary apparatus (such as a wire clip, tile hook, skirt as shown in FIG. 67 and/or other components or structures). Spring bracket 6710 may be fabricated from any rigid, semi-rigid, or self-supporting flexible material, such as formed by a steel (or other metal), plastic, composite, or other suitable material plate or the like and may have a thickness such as 3 mm (usually between 1 to 6 mm if steel). Spring bracket 6710 may contain flanges, protrusions, tabs, or the like, such as tabs 6716 that are adapted to fit loosely within groove 6722 between bearing surfaces. Spring bracket 6710 may further include a long bracket, lever, or arm, or the like, such as spring arm 6718 adapted to be at least partially flexible or plastically deformable when pressed by hand or with tools. The end of spring arm 6718 may be bent or otherwise formed with one or more flange(s), tab(s), or the like, such as split tab 6724, adapted such that at least a portion of split tab 6724 (shown at 6732) will fit in groove 6722 for a purpose of providing a holding force that maintains a pivot-fit connection between spring bracket 6710 and groove 6722. Thus, spring bracket 6710 may have a split tab 6724 with one or more engagement or retaining tabs, such as tab clip 6732 and one or more guiding or alignment tabs, such as guiding tab 6734. Guiding tab 6734 may be provided as part of split tab 6724 of spring bracket 6710 to permit movement or guidance of the tab end of bracket 6710, for example to laterally move tab clip 6732 into groove 6722 (final position as shown in FIG. 67) after spring arm 6718 is pressed down to a position such that tab clip 6732 is below an upper edge of groove 6722.

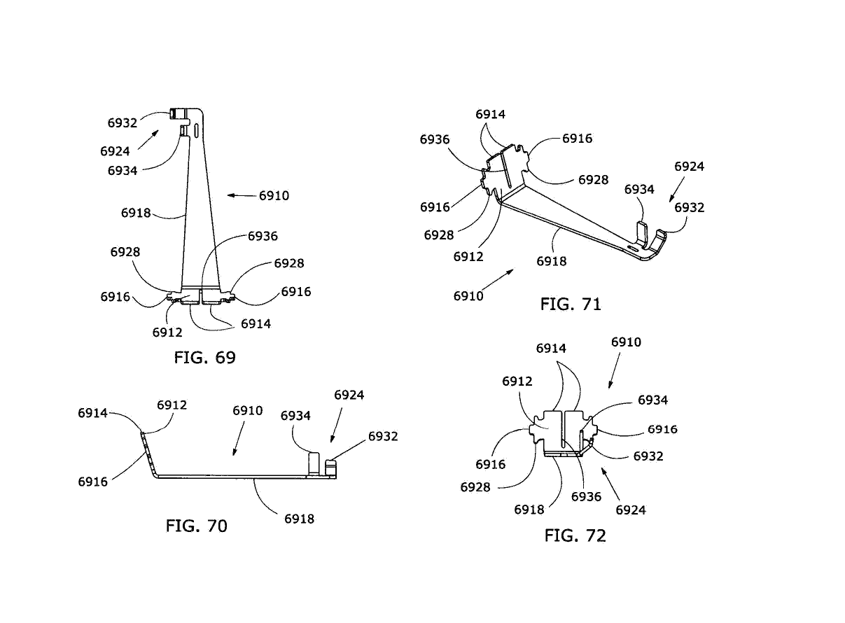

Referring now to FIGS. 69-72, wherein like numerals refer to like structures, another embodiment of a spring bracket is shown. A spring bracket such as spring bracket 6910 may include a base 6912, consisting of one or more retaining portions 6914, the space between forming slots 6936. The base 6912 may be 36.4 millimeters in length, or a longer or shorter length, and 30 millimeters wide excluding tabs 6916, though that dimension may also be greater or lesser. Retaining portions 6914 may be of equal, similar, or differing dimensions. Tabs 6916 with pivot portions 6928 may extend from either side of the base 6912. These tabs may be of equal, similar, or differing dimensions. A spring arm 6918 may meet the base 6912 at an angle of one hundred five (105) degrees, another obtuse angle, an acute angle, or a ninety-degree angle and may taper as it extends away from the base 6912. The spring arm 6918 may have a length of 139.3 millimeters or some other length, and may taper from a width of 30 millimeters where it meets the base 6912 to 10 millimeters where it meets the split tab 6924, though these dimensions may vary. A split tab 6924 may extend from the far end of the spring arm 6918, consisting of a guiding tab 6934 and a tab clip 6932. The guiding tab 6934 may extend up from the spring arm 6918 at a ninety-degree angle, or a greater or lesser angle. The tab clip 6932 may extend up from the spring arm 6918 such that it form a 140 degree angle with the top surface of the spring arm 6918, though this angle may vary from embodiment to embodiment. The thickness of the spring bracket 6910 and its components may be 2.4 millimeters, 2.1 millimeters, or some other thickness.

Referring again to FIGS. 67-68, a spring bracket 6710 is shown as it connects a PV module to an array skirt. To install, spring bracket 6710 may be positioned such that split tab 6724 is above a top surface of PV module 6720 (the terms “above”, “below”, “upper”, and “lower” imply a skyward facing PV module, with the PV laminate facing towards the sky, and away from the roof or other support surface, where “up” is substantially facing towards the sky, and “down” is substantially facing away from the sky) as shown in FIG. 68. Spring bracket 6710 may then be moved laterally toward PV module 6720 until one of tabs 6716 is located at least partially inside groove 6722 and spring arm 6718 is approximately parallel with the length of groove 6722, as shown in FIG. 67. In some embodiments a second PV module and/or other ancillary apparatus (such as a wire clip, tile hook, array skirt (as shown in FIG. 67) and/or other components or structures) may be placed adjacent to and usually essentially coplanar with PV module 6720 such that one of tabs 6716 is at least partially inserted into a groove 6726 on the ancillary apparatus, components, or structures, such as skirt 6750. Next spring arm 6718 may be pressed down toward opening 6758 beneath PV module 6720 with an external installation force (shown in FIG. 68 at F) towards PV module 6720 causing spring bracket 6710 to rotate at the pivotal connection point, such as pivot portion 6728, until one or more of tabs 6716 contact bearing surfaces in groove 6722 and/or groove 6726. Once one or both tabs 6716 is in contact with a bearing surface, spring arm 6718 deflects until at least one protrusion of split tab 6724, shown at tab clip 6732, is positioned below an upper bearing surface of groove 6722 (or alternatively, a groove, such as groove 6726—not shown) at which point at least a portion of split tab 6724, at tab clip 6732, enters groove 6722. Guiding tab 6734 may be used to laterally position tab clip 6732 into the most effective position in groove 6722. When the external force on spring arm 6718 is removed, at least a portion of split tab 6724, at tab clip 6732, is in forceful contact with a bearing surface in groove 6722 (or alternatively, groove 6726—not shown), a downward force is maintained on the bearing surface by at least one of tabs 6716. In some embodiments tabs 6716 may deform a portion of groove 6722 and/or groove 6726, one purpose for such deformation would be to create an electrical ground bond therebetween. In still other embodiments some or all structures or parts may be made of plastic, rubber, resin, non-conductive composites, or the like, or other non-electrically-conducting material, thereby not requiring or providing electrical grounding.

Guiding tab 6734 may also be used, for example, to disengage tab clip 6732 of spring bracket 6710 from a groove as by pushing downward (anti-skyward) on or near guiding tab 6734 until tab clip 6732 is not locked into groove 6722, then using guiding tab 6734 to laterally move tab clip 6732 out of groove 6722. This arrangement may also permit a PV module 6720 and a second PV module or ancillary device, such as skirt 6730 to be proximately and usually essentially co-planarly positioned with spring bracket 6710 slid between and with tabs 6716 inserted at least partially into grooves 6722 and 6726 before applying an external installation force (shown in FIG. 68 at F) towards PV module 6720 for connection together.

Spring bracket 6710 may also be provided with twist enablement, such as by utilization of a twist-enabling slot between the retaining portions 6714, such as slot 6736. When a spring bracket without slot 6736 is installed into (or disengaged from) a first groove 6722 (as shown in FIGS. 67 and 68) or groove 6726 (as shown in FIG. 67) and then an external installation force F (shown in FIG. 68 at F) towards PV module 6720 is exerted, the tab 6716 which is not secured into a groove will tend to twist or be torqued out of planar alignment with the secured tab 6716, making insertion into a groove of another device more difficult. Slot 6736, which may be stamped, milled, cut or otherwise formed into base 6712 of spring bracket 6710 usually at least partially between tabs 6716, may act to permit some deflection or twisting of one tab 6716 without substantial deflection of the other tab 6716 from its original co-planar position. Although spring bracket 6710 is shown as designed for clockwise rotation for connection to module 6720, it may be easily configured for counter-clockwise rotation. Also, other modifications will occur to one of skill in the art while remaining within the scope of this disclosure.

Array Skirt

Referring now to FIGS. 73-77C, wherein like numerals refer to like structures, embodiments of an array skirt are shown with non-limiting embodiments of components that the array skirt may engage.

Referring now to one embodiment, particularly to FIGS. 73-74, wherein like numerals refer to like structures, a skirt 7350 is shown in perspective at FIGS. 73 and 74 and with a cut away view at FIGS. 73A. Skirt 7350 may consist of a screen 7352, a top surface 7353, a spacer 7364, a rear surface 7356 that may include a groove 7354 with an upper lip 7357 and a lower lip 7359, a boss 7368, a bottom section 7355, and a reverse boss 7366. For the purpose of this paragraph, “up” or “upward” means skyward, “down” or “downward” means away from the sky, “front” or “forward” refers to the screen side of the array skirt, and rear, back, or backward refers to the rear surface side of the array skirt. The screen 7352 may extend upward at a forty-five degree angle, or an angle between zero degrees and forty five degrees or an angle between forty five degrees and ninety degrees, from the reverse boss 7366 to the top surface 7353. The screen may be flat or curved, or may consist of multiple panels that meet at the same angle or different angles. The spacer 7364 may extend backward from the rear edge of the top surface 7353, above the upper lip 7357. The groove 7354 may extend horizontally along the rear surface 7356 between the upper lip 7357 and lower lip 7359. The bottom section 7355 may extend backward from the back of the screen 7352, intersecting the bottom of the rear surface 7356 at a right angle, an angle greater than ninety degrees, or an angle less than ninety degrees. The bottom section 7355 may be flat or curved, or may include a combination of flat sections and/or curved sections. The boss 7368 may connect to the bottom of the bottom section 7355 beneath the groove 7354. The boss may be C-shaped, polygonal with an opening, or another shape as known to one skilled in the art. The reverse boss may be in the shape of a backward C, may be polygonal with an opening, or another shape as known to one skilled in the art. The array skirt may be extruded, cast, forged, or otherwise created, formed or manufactured as known to one skilled in the art. The array skirt may be formed of aluminum, another metal, composite, plastic, or other material as known to one skilled in the art.

Skirts for use with PV modules, or arrays of PV modules are shown and disclosed in detail at U.S. patent application Ser. No. 13/316,450 entitled: “Skirt for Photovoltaic Arrays”, filed approximately Dec. 9, 2011; which is incorporated by reference herein in its entirety. In the currently disclosed embodiment, a PV module array skirt may provide many benefits including, but not limited to, improved aesthetics, improved fire safety, improved installation speed, improved installation safety, improved structural performance, and allowance of sufficient airflow to adequately reduce the temperature of the PV array, the efficiency of which can be negatively impacted by excessive temperature. An array skirt may also partially or fully obscure the air gap and mounting hardware located beneath a PV array. The embodiments disclosed herein may also reduce installation cost by reducing the number of parts required for installation, as discussed in detail below. FIGS. 76A-76B show a profile view of an embodiment of a skirt, such as skirt 7650, which is similar to skirt 7350 as shown and described in FIG. 73 and others as well as to other skirts, as it connects to a coupling such as coupling 7602. Couplings for use with PV module or arrays of PV modules are shown and disclosed in detail at US Provisional Patent Application 61,737,066 entitled “Connecting Components for Photovoltaic Arrays,” filed approximately Dec. 13, 2012, which is incorporated by reference herein in its entirety. A coupling such as coupling 7602 may be the coupling of a mounting foot, such as mounting foot 7601, which may further include a key portion 7603, a tongue portion 7604, an upper jaw 7605, a grounding clip 7606, a tail 7607, a support 7608, a base 7609, a stud 7610, and flanges 7611. The profile of such a skirt design may allow for a pivot-fit connection of skirt 7650 to a coupling such as coupling 7602. Regarding FIGS. 76A and 76B, coupling 7602 is shown as located above a mounting foot, such as foot 7601 which may have a base portion, such as base 7609. Coupling 7602 may also allow for a pivot-fit connection for a PV module (not shown in FIGS. 76A and 76B) having a frame containing a groove on an outside surface. A pivot-fit connection between the components and grooves may be achieved by presenting male portions of coupling 7602 to female grooves in the module and in the skirt. The grooves may then seat at least partially over the male portions of the coupling 7602 and then rotate down, as indicated in FIGS. 76A and 76B, until the angle of the groove 7654 substantially aligns with the axis of the male portions, as more fully described in the patent application noted above. To complete the pivot-fit connection, the PV module or skirt 7650 is simply pivoted down to its final angular orientation in the PV array. This final rotation causes bearing portions in the respective groove to bear against the male portions of the coupling 7602 to restrain the PV module or skirt 7650 against upward or downward movement. The coupling may still allow for adjustment of the PV module position in the plane of the PV array to account for tolerance variations.

FIGS. 77A-77C show a perspective view of an embodiment of a skirt, such as skirt 7750 with a groove 7754 located on a surface, such as surface 7756. Skirt 7750 is similar to Skirt 7350 as shown and disclosed in FIG. 73, skirt 7650 as shown and disclosed in FIG. 76, and others, as well as other skirts. In the presently disclosed skirt 7750 embodiment, skirt 7750 is formed, constructed or machined to have a spacer or stand-off feature, shown as hook-shaped (in cut-away, profile view) spacer 7764 which may eliminate a gap or separation between skirt 7750 and an interlock which may be used to connect sections of skirt 7750 together. Skirt 7750 may also be provided with a female receiving portion, such as C-shaped (in cut-away, profile view) boss 7768 and a reverse C-shaped (in cut-away, profile view) reverse boss 7766. Boss 7768 and reverse boss 7766 are sized, shaped, and otherwise adapted to receive and hold portions of an anti-rotation component or slidable retainer, such as a grip (discussed in detail below). Referring now to FIG. 75A, a grip such as grip 7570 is shown, as is an array skirt such as array skirt 7550, which is similar to skirt 7350 as shown and disclosed in FIG. 73 and others, skirt 7650 as shown and disclosed in FIG. 76 and others, as well as to other skirts. Grip 7570 may be attached to skirt 7550. To install grip 7570 onto skirt 7550, a protrusion 7574 on grip 7570 is inserted or “snapped into” boss 7568; then the tab 7572 of grip 7570 is inserted or “snapped into” reverse boss 7566.

Referring now to FIGS. 77A-77C, embodiments of an array skirt 7750, a leveling foot 7701 (alternatively and without limitation designated as a mounting foot) with a coupling 7702 is shown, as is a grip 7770 and an array skirt 7750. Array skirt 7750 is similar to Skirt 7350 as shown and disclosed in FIG. 73, skirt 7650 as shown and disclosed in FIG. 76, and others, as well as to other skirts. Grip 7770 is similar to grip 7570 as shown and described in FIG. 75 and others, as well as to other grips. Foot 7701 is similar to foot 7601 as shown and described in FIG. 76A and others, as well as to other feet. There may be different coupling shapes, or shaped spaces between coupling 7702 and an associated foot 7701. Thus, grip 7770 is shown having different shaped mating portions 7776A or 7776B (discussed in detail below) adapted to fit or mate with alternate couplings. Skirt 7750 connects to coupling 7702 as shown and described above. Grip 7770 connects to Skirt 7750 as shown and described above. Grip 7770 then connects to coupling 7702 by moving laterally toward coupling 7702 until coupling 7702 is partially cradled in mating portion 7776B and flush against central stopper 7778 as shown in FIGS. 77B and 77C. The role of grip 7770 is discussed in further detail below.

Referring now to FIGS. 78A-78C, array skirt 7850 is shown attaching, as described above, to an alternate embodiment of a coupling 7802 of a foot 7801 using a different embodiment of a mating portion, mating portion 7876A, of a grip 7870. Array skirt 7850 is similar to array skirt 7750 as shown and described in FIG. 77A and others, to Skirt 7350 as shown and disclosed in FIG. 73 and others, to skirt 7650 as shown and disclosed in FIG. 76 and others, as well as to other skirts. Foot 7801 is similar to foot 7701 as shown and described in FIG. 77A and others, to foot 7601 as shown and described in FIG. 76A and others, and to other feet. Grip 7870 is similar to grip 7770 as shown and described in FIG. 77B and others, to grip 7570 as shown and described in FIG. 75 and others, and to other grips.

In summary, disclosed is an installed photovoltaic array comprising a photovoltaic module (6720, 9717, 10320), a skirt (6750, 7350, 7550, 7650, 7750, 7850, 8150, 9050, 9150, 9250, 9750) covering at least a portion of an opening (6758, 10315) beneath the photovoltaic module (6720, 9717, 10320), and a spring bracket (6710, 6910) connecting the skirt (6750, 7350, 7550, 7650, 7750, 7850, 8150, 9050, 9150, 9250, 9750) to the photovoltaic module (6720, 9717, 10320). The spring bracket may comprise a base portion (6712, 6912), an arm (6718, 6918) extending outward from the base portion (6712, 6912), and a retaining portion (6914) near an end of the arm (6718, 6918). The arm (6718, 6918) may act as a flexible lever, reducing the input force required to rotate the base portion (6712, 6912) into an installed position and flexing to enable the retaining portion (6914) to lock onto the photovoltaic module (6720, 9717, 10320) and skirt (6750, 7350, 7550, 7650, 7750, 7850, 8150, 9050, 9150, 9250, 9750).

Also disclosed is the installed photovoltaic array as noted above where the retaining portion (6914) bears against at least one of the photovoltaic modules (6720, 9717, 10320) and one of the skirts (6750, 7350, 7550, 7650, 7750, 7850, 8150, 9050, 9150, 9250, 9750) with a spring force that substantially results from the flexing of the arm (6718, 6918). Also disclosed is the installed photovoltaic array as noted above, where the retaining portion (6714, 6914) comprises a tab (6716, 6916), the tab (6716, 6916) at least partially retained by at least one of the photovoltaic modules (6720, 9717, 10320) and one of the skirts (6750, 7350, 7550, 7650, 7750, 7850, 8150, 9050, 9150, 9250, 9750) in an installed position. Also disclosed is the installed photovoltaic array as noted above, where the arm (6718, 6918) comprises an elongate form extending in a direction substantially parallel to a plane of a top surface of a light receiving side of a photovoltaic laminate (10314) of the photovoltaic module (6720, 9717, 10320). Also disclosed is the installed photovoltaic array as noted above, where the spring bracket (6710, 6910) connects to a groove (6722, 10322) in a frame (8021, 9021, 9321) of the photovoltaic module (6720, 9717, 10320). Also disclosed is the installed photovoltaic array as noted above, where the spring bracket (6710, 6910) connects to a groove (6726, 7354, 7554, 7654, 7754, 7854, 9054, 9154, 9254, 10654, 9754) in the skirt (6750, 7350, 7550, 7650, 7750, 7850, 8150, 9050, 9150, 9250, 9750). Also disclosed is the installed photovoltaic array as noted above, where the spring bracket (6710, 6910) captures at least a portion of the photovoltaic module (6720, 9717, 10320).

Rotating Trim Bracket

Referring now to one embodiment, particularly to FIGS. 79A-81, wherein like numerals refer to like structures, a rotating trim bracket is shown. A rotating trim bracket (also known as a skirt bracket) such as rotating trim bracket 7900 may consist of an upper portion 7901, a lower portion 7902, and a connection portion 7903. The upper portion may include a lower horizontal panel 7904 with an aperture 7905, an upper vertical panel 7906 with one, two, or more groove hooks 7907A and 7907B, a top panel 7908, and a skirt hook 7909. The lower portion may include a coupling panel 7910 with an aperture 7911, a frame catch 7912, a vertical panel 7913, a support plate 7914, and a connection panel 7915 with an aperture 7916. The connection portion 7903 may include a setting 7917 with an aperture 7918 and a magnet 7919 with an aperture 7920. For the purpose of this paragraph, (i) “up” or “upward” means skyward, (ii) “down” or “downward” means away from the sky, (iii) “front” or “forward” refers to the connection portion end of the rotating trim bracket, where the rotating trim bracket is oriented such that the upper vertical panel 7906 is parallel to the vertical panel 7913 and the frame catch 7912 points in the same direction as the groove hooks 7907A and 7907B, and (iv) rear, back, or backward refers to the direction opposite the “front” or “forward” direction. The upper vertical panel 7906 of the upper portion 7901 may extend thirty, fifty, or eighty millimeters vertically, or some other height. The lower horizontal panel 7904 may extend forward from the bottom edge of the upper vertical panel 7906 at a ninety-degree angle, at a 100-degree angle, at an 80-degree angle, or at another angle between zero and 180 degrees. The upper vertical panel 7906 and lower horizontal panel 7904 may be the same width or different widths and may be the same thickness or different thicknesses. Aperture 7905 may appear in the center of lower horizontal panel 7904 or off-center. Groove hooks 7907A and 7907B may extend from the sides of the vertical panel, protruding backward and curving or angling downward or upward. Groove hooks 7907A and 7907B may extend from the middle of the sides of the upper vertical panel 7906 or from a higher or lower position on the upper vertical panel 7906. Groove hooks 7907A and 7907B may connect to the upper vertical panel 7906 at the same height or at different heights. Groove hooks 7907A and 7909B may extend perpendicular to the upper vertical panel 7906 or at an angle between zero degrees and ninety degrees or at an angle between ninety degrees and one hundred eighty degrees. Top panel 7908 may extend from the top edge of upper vertical panel 7906 at a ninety degree angle or another angle, extending forward over and parallel to lower horizontal panel 7904. The upper vertical panel 7906 and top panel 7908 may be the same width or different widths and may be the same thickness or different thicknesses. Skirt hook 7909 may then extend downward from top panel 7908 until folding forward and up to form an U shape, with its end curving backward, pointing straight up, or flaring forward. Top panel 7908 and skirt hook 7909 may be the same width or different widths and may be the same thickness or different thicknesses. Lower horizontal panel 7904 may connect to coupling panel 7910 by means of a pivot hinge, a nut and bolt, a grommet, or some other method (not shown) as known to one of skill in the art that permits upper portion 7901 and lower portion 7902 to pivot with respect to one another. The coupling panel 7910 may be the same width and thickness as the lower horizontal panel or a different width and thickness. Aperture 7911 may appear in the center of coupling panel 7910 or elsewhere on the panel, and may be the same size as aperture 7905 or a different size. The frame catch 7912 may extend backward from the coupling panel in a sideways S shape or some other non-linear shape and may deform when downward pressure is applied to it. The lower vertical panel 7913 may extend from the end of the coupling panel opposite the frame catch 7912 at a ninety degree angle, or at an 80 degree angle, a 100 degree angle, or any other angle between zero and one hundred eighty degrees. Support plate 7914 may then extend forward from the bottom edge of the lower vertical panel 7913 at a ninety degree angle, one hundred thirty degree angle, seventy five degree angle, or any other angle between zero and one hundred eighty degrees. Connection panel 7915 may extend forward and downward from the front edge of the support plate 7914 at a forty-five degree angle, thirty degree angle, fifty degree angle, or any other angle between zero and ninety degrees. The connection panel 7915 may be rectangular or may have a rounded end. Aperture 7916 may appear in the center of or elsewhere on connection panel 7915. Setting 7917 may be cylindrical, cubic, or some other shape that may house magnet 7919. Setting 7917 may have an aperture 7918 that may appear in its center or elsewhere on the back of setting 7917. Aperture 7918 may be the same size as aperture 7916 or a different size. Magnet 7919 may be cylindrical and of a slightly smaller diameter than a cylindrical setting 7917, or may be another shape that permits it to nest within setting 7917. Magnet 7919 may have an aperture 7920 that may be the same size as apertures 7916 and/or 7918 or a different size. Magnet 7919 and setting 7917 may connect to connection panel 7915 using a bolt and nut, grommet, glue, solder, or other connector or adhesive (not shown). Alternatively, magnet connection portion 7903 may be replaced with a second skirt hook, or some other manner of affixing an array skirt as discussed in detail below. Rotating trim bracket 7900 may be made of sheet metal, plastic, or another material known to one of skill in the art. Rotating trim bracket 7900 may connect an array skirt to a PV module or array, as described below.

Referring now to FIGS. 80A-80C, a rotating trim bracket is shown connected to the frame of a PV module. A rotating trim bracket such as rotating trim bracket 8000, which is similar to rotating trim bracket 7900 as shown and described in FIG. 79A and others and to other rotating trim brackets, is shown connecting to a frame 8021 with a groove 8022 extending horizontally across an outer surface 8023. The groove 8022 is bounded on its upper edge by an upper lip 8024 and on its lower edge by a lower lip 8025. With the lower portion 8002 pivoted ninety degrees to either side, the groove hooks 8007A and 8007B may be placed in the groove 8022 such that the groove hooks 8007A and 8007B fit over and behind the lower lip 8025 and the back surface of the upper vertical panel 8006 contacts the outer surface 8023. Lower portion 8002 may then be pivoted such that the frame catch 8012 rotates directly underneath the bottom surface 8026 of the frame 8021 and connection portion 8003 extends forward in the opposite direction of groove hooks 8007A and 8007B, as shown in FIG. 80C. Part of the upper surface of the frame catch 8012 contacts the bottom surface 8026 of the frame 8021, securing the rotating trim bracket 8000 to the frame 8021.

Referring now to FIG. 81, an array skirt is shown connected to a frame by a rotating trim bracket. An array skirt such as array skirt 8150 is similar to array skirt 7350 as shown and described in FIG. 73 and others, and to other array skirts. Array skirt 8150 may include a screen 8152, a top surface 8153, a top flange 8151, and a bottom flange 8160. A frame such as frame 8121 is similar to frame 8021 as shown and described in FIG. 80 and others, and to other frames. A rotating trim bracket such as rotating trim bracket 8100 is similar to rotating trim bracket 7900 as shown and described in FIG. 79, and to other rotating trim brackets. Array skirt 8150 may connect to rotating trim bracket 8100 by sliding the top flange 8151 into the skirt hook 8109 and touching the back side of the screen 8152 to the magnet nested in fitting 8117. Alternatively, in an embodiment of a rotating trim bracket that uses a second skirt hook instead of a magnet, the bottom flange of the skirt may slide into the second skirt hook (not shown).

In some embodiments, support plate 8114 may be shorter than the length of skirt 8150 or the side of PV module frame 8121; for example, any one or more support plate(s) 8114 may be of a width (into/out-of the paper) of 1, 2, 2.5, 2.75, 3, or 6 inches or other pre-defined or field-produced length. With shorter length support plate(s) 8114, skirt 8150 may be supported on one or more (usually multiple) support plates. Alternatively, support plate may be the same length or longer (into/out-of the paper) than the length of skirt 8150 or the side of PV module frame 8121.

Skirt Base

Referring now to one embodiment, particularly to FIGS. 82-85, wherein like numerals refer to like structures, a skirt base 1150 is shown in cut-away cross-section with a groove 1152 which may be connected to a coupling (not shown) in the manner described above or previously in one or more of the patent cases incorporated herein. Skirt base 1150 may be made of aluminum, plastic, composite(s) or other materials in a length usually, but not necessarily, longer than a length of a PV module frame where a skirt will be mounted. The longer length of skirt base 1150 need not be excessive, in some embodiments the length of skirt base 1150 may be only ⅛, ¼, ½, ¾, ⅞, 1, 1.5, 2 or more inches longer than a length of a PV module frame where a skirt will be mounted. In other embodiments, skirt base 1150 may be shorter than a length of a PV module frame member. Regardless of skirt base 1150 length, during installation of PV modules, a length of a skirt base 1150 is usually positioned to span the space or seam between two (or more) PV module lengths to provide additional structural support for the PV modules in the x, y and/or z direction(s).

One purpose or function of skirt base 1150 is to function as a jig and permit a stiffening member, such as a stiff T-shaped cross-section supporting or member, such as T-bar 1154, to be used with skirt base 1150 during installation of PV modules into an array, with T-bar 1154 able to be removed and re-used for other installation jobs. T-bar 1154 may be constructed or sized to be approximately as long as skirt base 1150, or may be longer or shorter as desired. In one embodiment, T-bar 1154 is longer than skirt base 1150 and approximately as long as a skirt that may be installed, such as skirt 1158. In another embodiment, T-bar 1154 is approximately the same length as skirt base 1150. In yet another embodiment, T-bar 1154 is shorter than skirt base 1150 and approximately as long as a skirt that may be installed, such as skirt 1158.

Skirt base 1150 may also be cast, manufactured to have, or otherwise provided with one or more additional features as explicitly disclosed or as would occur to one of skill in the art. Skirt base 1150 is shown with a T-bar 1154 receiving slot, such as slot 1156, extending essentially the entire length of the Skirt base 1150, as well as a spacer 1160 which may perform essentially the same function as spacers 7664, 7764, and 7864 as shown in, and described regarding, FIGS. 76A-78C. Skirt base 1150 may also be provided with a lower feature, such as lip 1162 with opening 1164 which may be used to affix, secure, connect or couple to one or more ancillary devices, such as rodent screen 1166. Rodent screen 1166 may be connected to lip 1162 as by snapping into or screwing, riveting, gluing, epoxying or otherwise securing a portion of rodent screen 1166 to lip 1162 or into opening 1164 of lip 1162.

During mounting of PV modules into an array, one or more mounting feet (not shown) are secured to a support surface, such as a roof (not shown). Each of or at least a plurality of the mounting feet are associated with a respective coupling (not shown). Groove 1152 of skirt base 1150 may be rocked-onto or otherwise secured to one or more coupling(s) in the manner described above, either before, after or simultaneously with the securing of PV module frame groove(s) being secured to the opposing side of the one or more coupling(s). Skirt base 1150 provides further or greater structural rigidity and/or weight/load support to the structure than would be achieved without such base, or than would be achieved by mounting a skirt as previously described. To provide even further or greater structural rigidity and/or weight/load support, T-bar 1154 may be inserted into slot 1156 of skirt base 1150 as shown in FIG. 84. As shown, T-bar 1154 is barely narrower than the x-direction width of slot 1156, and may contact the upper surface of skirt base 1150. T-bar 1154 may also have different cross sections, including a straight line or inverted-L configuration. The length of T-bar 1154 may permit it to reach the bottom of slot 1156 (not shown), or not to reach the bottom (as shown). The T-bar may then be removed (for use at another time) and ancillary devices, such as rodent screen 1166 and/or skirt 1158 may be attached to skirt base 1150.

Referring now more particularly to FIG. 85, skirt 1158 may be affixed, secured, connected or coupled to skirt base 1150 in any manner occurring to one of skill in the art, but is shown with deformed sections, such as dimples 1168 and 1170 which may be a long groove extending along the length of skirt 1158, or localized dimples having a circular cross-section when looking down or in the y-direction. Dimple 1168 may be connected to any edge of and/or partially within slot 1156 as by snapping into or screwing, riveting, gluing, epoxying or otherwise securing a portion of Dimple 1168 to an edge, corner, wall, or at least partially into slot 1156. Similarly, Dimple 1170 may be connected to any edge of and/or partially within a slot or hole formed by or in spacer 1160 as by snapping into or screwing, riveting, gluing, epoxying or otherwise securing a portion of Dimple 1170 to an edge, corner, wall, or at least partially into a slot formed by or in spacer 1160.

Tile Hook

Referring now to an embodiment, particularly to FIGS. 86-88, wherein like numerals refer to like structures, a tile hook, such as tile hook 8600 is shown in perspective at FIGS. 86-87 and with a cut away view at FIG. 88. Tile hooks for use with PV modules, or arrays of PV modules, are shown and disclosed in detail at U.S. patent application Ser. No. 13/325,054 filed approximately Dec. 13, 2011 and Ser. No. 13/402,860 filed approximately Feb. 22, 2012, both of which are entitled: “Discrete Attachment Point Apparatus and System for Photovoltaic Arrays”, both of which are incorporated by reference herein in their entireties.

A tile hook such as tile hook 8600 may include an arm portion 8601 with a tile hook slot 8602 and one or more notches 8603A and 8603B. Tile hook 8600 may further include base portion 8604 which may consist of a horizontal panel 8605 with one or more substrate apertures 8606A-8606L and a vertical panel 8607 with one or more hook apertures 8608A-8608C. Tile hook 8600 may further include bolt 8609, washer 8610, and nut 8611 or another fastening mechanism known to one of skill in the art. For the purpose of this paragraph, “up” or “upward” means skyward, “down” or “downward” means away from the sky, “front” or “forward” means toward the base portion end of the tile hook, and rear, back, or backward means toward the arm end of the tile hook. Tile hooks, such as tile hook 8600 may be comprised of components made from aluminum, steel, or other hard and/or rigid materials, including suitable metals, plastics, composites and the like. The base portion 8604 and arm portion 8601 of the tile hook may be 6 millimeters thick, 5 millimeters thick, 10 millimeters thick, or some other thickness, and they may be of the same thickness or different thicknesses. The base portion 8604 may be (i) 160 millimeters wide, 100 millimeters wide, 200 millimeters wide, or another width, (ii) 67.5 millimeters deep, 50 millimeters deep, 100 millimeters deep, or another depth, and (iii) 37 millimeters high, 50 millimeters high, 30 millimeters high, or another height. Horizontal panel 8605 may meet vertical panel 8607 at a ninety degree angle, at an eighty degree angle, at a 110 degree angle, or at some other angle between zero and one hundred eighty degrees. Substrate apertures 8606A-8606L may be circular such as substrate apertures 8606A and 8606G, oblong such as substrate apertures 8606B-8606E and 8606H-8606L, or another shape or a variety of shapes. Substrate apertures 8606A-8606L may appear in rows, in rings, at random, or in another formation. Hook apertures 8608A-8608C may be circular, oblong, or another shape, may be centered vertically along the width of vertical panel 8607, may be staggered at different heights along vertical panel 8607, may be evenly distributed across the width of vertical panel 8607, or may be unevenly distributed across that width. Arm portion 8601 may be (i) 145 millimeters high, 140 millimeters high, 160 millimeters high, or some other height (ii) 35 millimeters wide, 50 millimeters wide, 30 millimeters wide, or some other width, and (iii) in approximately the shape of a question mark, in approximately the shape of a G, or some other shape. Tile hook slot 8602 may be centered in the top-most portion of arm portion 8601 or may be off center. Notches 8603A-8603B may be cutouts in the sides of arm portion 8601 and may be curved or angular. The base portion 8604 of tile hook 8600 may be secured to a substrate (not shown) by applying screws, bolts, or another fastener to one or more of the substrate apertures.

In the currently disclosed embodiment, a tile hook 8600 is shown with a tile hook slot 8602 which may be used to attach to a leveling foot or a mounting bracket or foot, such as but without limitation mounting foot 7601, mounting foot 7701, or mounting foot 7801, which may in turn connect to and/or support, without limitation, a skirt such as skirt 7650, skirt 7750, or skirt 7850 as shown in FIGS. 76A-78C.

Tile hook 8600 may be used to connect to or mount various tile mount hardware, as with common fasteners such as bolts, nuts, and washers which may be fastened through holes or slots such as clamp holes (not shown) and/or tile hook slot 8602. Clamp holes and/or tile hook slots may be in various quantities and may be round, oval, slotted, or the like.

Grip

Referring now to FIGS. 75-75A, wherein like numerals refer to like structures, embodiments of a grip are shown. A grip such as grip 7570 may include an arm 7571 ending in a tab 7572 and having a trigger 7573. Grip 7570 may further have a body 7575 that includes a protrusion 7574 and one or more mating portions 7576A and 7576B bounded by a front stop 7577, a central stopper 7578, and one or more back stops 7579A and 7579B. For the purpose of this paragraph, “up” or “upward” means skyward, “down” or “downward” means away from the sky, “front” or “forward” refers to the tab end of the grip, and rear, back, or backward refers to the back-stop end of the grip. Arm 7571 extends from body 7575 to tab 7572 and may be straight or curved, may consist of a series of angled panels meeting at the same angle or different angles, or may be a combination of straight and curved portions. Tab 7572 may be wider, narrower, or the same width as arm 7571, though if wider the extra width may permit the tab to move laterally along a boss (as discussed below) more easily than a narrower tab would permit. Tab 7572 may be thicker, thinner, or the same thickness as arm 7571. Trigger 7573 may extend downward from arm 7571 where arm 7571 meets tab 7572, or from a point on arm 7571 closer to body 7575, and then curve forward toward tab 7572. Body 7575 may create a U shape starting from the protrusion 7574, continuing downward to form front stop 7577, then curving backward to form the central stopper 7578 and mating portions 7576A and 7576B until ultimately extending upward once again, forming one or more back stops 7579A and 7579B. The central stopper 7578 may feature two notches 7581A and 7581B that may permit a lever such as a screwdriver to facilitate uninstalling a fully installed grip (as discussed below). Body 7575 may include cut outs 7580A and 7580B which may allow for the presence of a stud when fully installed (as discussed below). The length of the grip may be 126.9 millimeters, though the grip may of a longer length such as 150 millimeters, a shorter length such as 100 millimeters, or another length. The width of the grip may be 46 millimeters, though the grip may of a wider width such as 50 millimeters, a narrower width such as 35 millimeters, or another width. The height of the grip from the bottom of the tab to the top of the protrusion may be 27 millimeters, though the grip may be of a greater height such as 30 millimeters, a lesser height such as 20 millimeters, or another height.

Referring now to FIGS. 89A-89B wherein like numerals refer to like structures, another embodiment of a grip is shown. A grip such as grip 8970 is similar to grip 7570, as shown and described regarding FIG. 75A and others, and to other grips. Grip 8970 is also similar to other grips as would be understood by one of skill in the art. Grip 8970 may include, without limitation, an arm such as arm 8971, a groove such as groove 8982 formed by the space between a protrusion such as protrusion 8974 and a rise such as rise 8983, and one or more mating portions such as mating portions 8976A and 8976B. Grip 8970 may be fabricated or constructed from different materials such as plastic, composite, or other material as known in the art. Grip 8970 may be formed, molded, milled, or otherwise fabricated or constructed by a method as would be known to one with skill in the art. Grip 8970 may connect to an array skirt in a fashion similar to that of grip 7570, discussed above. Referring now to FIG. 90, and by way of example and not limitation, grip 8970 may connect to an array skirt by (i) positioning a grip such as grip 9070 under an array skirt such as array skirt 9050, which is similar to array skirt 7450 as shown and described in FIG. 74 and others and to other array skirts, (ii) orienting grip 9070 so that its arm 9071 extends toward the underside of array skirt 9050 and its groove 9082 faces boss 9068, and (iii) pressing boss 9068 into groove 9082 such that they “snap” together until they are connected as shown in FIG. 90. Once grip 9070 snaps onto boss 9068, grip 9070 may loosely connect to boss 9068 and may be removed by pulling or otherwise forcing away from array skirt 9050. While grip 9070 is connected to boss 9068, it may move laterally along the boss in a pre-mount state prior to its full and final installation where it engages the coupling of a mounting foot. Pre-mounting prevents the grip from detaching from the skirt, and may therefore guard against accidental fumbles of the grip during the installation process, as some installations may orient a PV array in an awkward or challenging position making it difficult for an installer otherwise to install the grip and increasing the likelihood that the installer may drop or fumble the grip. Pre-mounting may further facilitate installation by aligning the grip with the coupling of the mounting foot, as some installations may interfere with the installer's ability to see the components and manually align the grip with the coupling of the mounting foot. Pre-mounting may orient, align, or aim the grip such that subsequent lateral movement of the grip will seat the grip such that it engages the coupling of the mounting foot without further manipulation. Referring now to FIGS. 91A-91B, a grip such as grip 9170 may also engage with a coupling such as coupling 9102 on foot 9101. Grip 9170 is similar to grip 9070 as shown and described in FIG. 90 and others, to grip 8970 as shown and described in FIG. 89A and others, and to other grips. By way of illustration and not limitation, grip 9170 may engage with coupling 9102 as follows. First, coupling 9102 connects, as described above, to an array skirt such as array skirt 9150 which is similar to array skirt 7450 as shown and described in FIG. 74 and others and to other skirts. Next, grip 9170 also connects, as described above, to array skirt 9150. Then, grip 9170 may be moved laterally along boss 9168 toward coupling 9102. Lastly, a mating portion such as mating portion 9176B slides underneath and against coupling 9102 as shown in FIG. 91B until the coupling 9102 contacts the central stopper 9178. Grip 9170 may secure array skirt 9150 to coupling 9102. By way of illustration and not limitation, grip 9170 may prevent array skirt 9150 from pivoting upward when grip 9170 is both (i) connected to array skirt 9150 and (ii) engaged with coupling 9102. This prevents array skirt 9150 from disconnecting from coupling 9102. Referring now to FIGS. 92A and 92B, another embodiment of a grip is shown, connecting to the coupling of a foot and an array skirt. Grip 9270 is similar to grip 9070 as shown and described in FIG. 90 and others, to grip 8970 as shown and described in FIG. 89A and others, to grip 9170 as shown and described in FIG. 91A and others, to grip 7570 as shown and described in FIG. 75A and others, grip 7770 as shown in FIG. 77A and others, and to other grips. Grip 9270 may connect to coupling 9202 in the same manner as described above, but as shown in FIGS. 92A and 92B, grip 9270 connects to coupling 9202 from a different side than grip 9170 connects to coupling 9102 (as shown in FIGS. 91A and 91B) because the coupling 9202 is shaped to match the opposite mating portion 9276A.

Corner Caps

Referring now to FIGS. 93A-93C wherein like numerals refer to like structures, a corner cap is shown. A corner cap such as corner cap 9301 may include two screen portions such as screen portion 9304A and 9304B, two bottom portions such as bottom portions 9305A and 9305B, two top portions such as top portions 9306A and 9306B with one or more tabs such as tabs 9307A and 9307B, and an angle such as angle 9308. Corner cap 9301 may be made of aluminum, plastic, another metal or alloy, or other material as known in the art. For the purpose of this paragraph, “up” or “upward” means skyward, “down” or “downward” means away from the sky, rear, back, or backward refers to the direction in which the tabs extend away from the top portion, and “front” or “forward” refers to the opposite direction. Corner cap 9301 may be 0.437 millimeters thick, 0.627 millimeters thick, 0.5 millimeters thick, or another thickness. Each screen portion may be 196 millimeters long at its longest point, 127 millimeters long at its longest point, 210 millimeters long at its longest point, or another dimension. Each screen portion may extend upward at a forty-five degree angle, forty degree angle, fifty degree angle, or other angle between zero and ninety degrees that is compatible with the array skirt to which it attaches, discussed further below. FIG. 93A shows a perspective view of corner cap 9301. FIG. 93B shows an orthogonal view of corner cap 9301. FIG. 93C shows a rear perspective view of corner cap 9301. Referring now to FIGS. 94A-94B, corner cap 9301 is shown with an array skirt, such as array skirt 9407, which is similar to array skirt 7350 as shown and described in FIG. 73 and others. By way of example and not limitation, corner cap 9301 may connect to array skirt 9407 as follows. First, corner cap 9301 is aligned next to the array skirt 9407 such that screen portion 9304A is parallel to the extrusion 9408 of the array skirt 9407. Next, corner cap 9301 is moved laterally toward array skirt 9407 such that (i) the underside of the screen portion 9304A contacts or nearly contacts the extrusion 9408 and (ii) the upward-facing surface of the bottom portion 9305A contacts or nearly contacts boss 9409. Lastly, tab 9307A is bent downward toward the groove 9410 such that it semi-encircles spacer 9411. In some embodiments, corner cap 9301 may be moved laterally on the array skirt 9407 to bring the angle 9308 closer to or further from the edge of the array skirt 9407. In other embodiments corner cap 9301 may be secured by tabs similar to tab 9307A except already pre-bent to a shape that semi-encircles spacer 9411. In other embodiments corner cap 9301 may be further secured with screws. Corner cap 9301 may connect the edges of two perpendicular array skirts, for example and without limitation, two array skirts connected to perpendicular sides of the same PV module. Referring now to FIGS. 94C and 94D, corner cap 9301 may be installed by moving corner cap 9301 diagonally toward a corner where two perpendicular array skirts 9407 meet, then mating the two orthogonal sides of corner cap 9301 with the array skirts 9407, then folding over tabs 9307A, 9307B such that they semi-encircle spacers 9411 on the skirts 9407. A corner cap may cover gaps of various sizes between perpendicular array skirts by moving laterally over an array skirt as needed. A corner cap may provide improved aesthetics by eliminating gaps between perpendicular array skirts. If the edge of an array skirt does not align with the corner of a PV module, the corner cap may provide improved aesthetics by concealing the misalignment. Embodiments of corner caps such as corner cap 9301 may, without limitation, be designated “outside corner caps” as, once installed, the angle created by the corner cap points outward, away from the PV array.

Referring now to FIGS. 95A-95C, another embodiment of a corner cap is shown. A corner cap such as corner cap 9501 is similar to corner cap 9301 as shown and described regarding FIGS. 93A-93C and others, as well as other corner caps as would be understood by one of skill in the art. Corner cap 9501 may include two screen portions such as screen portion 9504A and 9504B, two bottom portions such as bottom portions 9505A and 9505B, two top portions such as top portions 9506A and 9506B with one or more tabs such as tabs 9507A-9507D, and an angle such as angle 9508. Referring now to FIGS. 95D and 95E, corner cap 9501 is shown connecting to an array skirt, such as array skirt 9550 which is similar to array skirt 7350 as shown and described in FIG. 73 and others, and to other array skirts. Corner cap 9501 may connect to array skirt 9550 in a similar manner that corner cap 9301 connects to array skirt 9450, discussed above. Embodiments of corner caps such as corner cap 9501 may, without limitation, be designated “inside corner caps” as, once installed, the angle created by the corner cap points inward, toward from the PV array.

Referring now to FIGS. 96A-96B, yet another embodiment of a corner cap is shown. A reversible inside/outside corner cap such as corner cap 9601 is similar to corner cap 9301 as shown and described regarding FIGS. 93A-93C and others and corner cap 9501 as shown and described regarding FIGS. 95A-95C and others, except for the reversible features as are described below. Corner cap 9601 may include two screen portions such as screen portions 9604A and 9604B, two wide surfaces such as wide surfaces 9605A and 9605B with one or more tabs such as tabs 9607A and 9607B, two narrow surfaces such as narrow surfaces 9606A and 9606B with two or more tabs such as tabs 9609A and 9609B, and a miter perforation such as miter perforation 9608. Corner cap 9601 may be made of aluminum, another metal or alloy, or other material as known in the art. By way of example and not limitation, corner cap 9601 may connect to an array skirt such as array skirt 9407 as follows. First, corner cap 9601 may be folded downward along the miter perforation until the narrow surfaces 9606A and 9606B are perpendicular to one another. Next, wide surfaces 9605A and 9605B may be folded toward narrow surfaces 9606A and 9606B until the wide surfaces 9605A and 9605B are parallel to the narrow surfaces 9606A and 9606B. Corner cap 9601 then connects to array skirt 940 in a similar manner as corner cap 9301. Alternatively, corner cap 9601 may be folded along the miter perforation in the opposite direction, thus reversing the corner cap 9601 so that it functions as an outside corner cap instead of an inside corner cap. Next, narrow surfaces 9606A and 9606B may be folded toward wide surfaces 9605A and 9605B until the narrow surfaces 9606A and 9606B are parallel to the wide surfaces 9605A and 9605B. Corner cap 9601 then connects to array skirt 9407 in the same manner as corner cap 9501.

Referring now to FIGS. 97A-971, wherein like numerals refer to like structures, one possible progression of installation steps for a PV array with an array skirt is shown. FIGS. 97A and 97B show the attachment of two adjacent array skirts such as array skirts 9750 using an interlock such as interlock 9712. Interlocks for use with PV modules, or arrays of PV modules are shown and disclosed in detail at U.S. patent application Ser. No. 12/830,249 entitled: “Pivot-Fit Frame, System and Method for Photovoltaic Modules”, filed approximately Jul. 2, 2010; which is incorporated by reference herein in its entirety. Interlock 9712 may include an interlock plate 9719 with two or more coupling apertures 9721A and 9721B, one or more lugs 9720A-9720C, and one or more jig marks 9722A-9722G. Interlock 9712 may further include two or more couplings 9714A and 9714B with a key portion 9713A-9713B and a tongue portion 9718A and 9718B. FIG. 97A shows two adjacent array skirts 9750 aligned and coincident to one another, with the key portions 9713A and 9713B of the couplings 9714A and 9714B of the interlock 9712 aligned with the grooves 9754 of the array skirts 9750. The key portions 9713A and 9713B are then moved into the grooves 9754, as shown in FIG. 97B, such that one key portion enters the groove of each array skirt 9750 and the interlock 9712 spans the two array skirts 9750. FIGS. 97C-97D show the interlock 9712 being secured to the array skirts 9750 using a lever tool 9723. The couplings 9714A and 9714B are rotated clockwise, causing the key portions 9713A and 9713B to grip the grooves 9754 of the array skirts 9750, securing the adjacent array skirts 9750. FIG. 97E shows the connected array skirts 9750 connecting to the couplings 9716 of leveling feet 9715 as shown and described in FIGS. 76A and 76B. Leveling foot 9701 (alternately and without limitation designated as a mounting foot) is similar to leveling foot 7601 as shown and described in FIG. 76A and others, and other leveling feet. Leveling foot 9701 is connected to a mounting block 9724 and flashing 9725, which are further connected to a support structure such as substrate 9726 supported by one or more joists 9727. Mounting blocks and flashing, alternately referred to as flashing devices among other designations and without limitation comprising a flashing plate, a block, and a seal, for use with PV modules or arrays of PV modules are shown and disclosed in detail at U.S. patent application Ser. No. 13/673,985 entitled “Solar Panel Attachment Method” filed approximately Nov. 9^{th}, 2012, which is incorporated by reference in its entirety. FIGS. 97F and 97G show the installation of a PV module 9717 onto a coupling 9702 to which an array skirt 9750 has already attached. FIG. 97H shows the installation of an adjacent PV module 9717 in the same fashion. FIG. 97I shows three adjacent PV modules 9717 installed with three adjacent array skirts 9750.

In summary of the above disclosures of grips and array skirts and their installation, disclosed is a photovoltaic array skirt, comprising a skirt portion (6750, 7350, 7550, 7650, 7750, 7850, 8150, 9050, 9150, 9250, 9750) covering at least a portion of an opening (6758, 10315) beneath a photovoltaic module (6720, 9717, 10320), a mounting foot (7601, 7701, 7801, 9101, 9201, 9701) connecting the skirt portion (6750, 7350, 7550, 7650, 7750, 7850, 8150, 9050, 9150, 9250, 9750) to a support structure (9726); and a slidable retainer (7570, 7770, 7870, 8970, 9070, 9170, 9270, 9770) at least partially connecting the skirt portion (6750, 7350, 7550, 7650, 7750, 7850, 8150, 9050, 9150, 9250, 9750) to the mounting foot (7601, 7701, 7801, 9101, 9201, 9701). The slidable retainer (7570, 7770, 7870, 8970, 9070, 9170, 9270, 9770) is laterally slidable along the skirt portion (6750, 7350, 7550, 7650, 7750, 7850, 8150, 9050, 9150, 9250, 9750) to disengage from the mounting foot (7601, 7701, 7801, 9101, 9201, 9701) and comprises a retaining feature (7574, 7572, 8974, 8977, 8983), the retaining feature (7574, 7572, 8974, 8977, 8983) enabling an adjustably secure connection of the slidable retainer (7570, 7770, 7870, 8970, 9070, 9170, 9270, 9770) to the skirt portion (6750, 7350, 7550, 7650, 7750, 7850, 8150, 9050, 9150, 9250, 9750) prior to connecting the slidable retainer (7570, 7770, 7870, 8970, 9070, 9170, 9270, 9770) to the mounting foot (7601, 7701, 7801, 9101, 9201, 9701).

Also disclosed is the photovoltaic array skirt as noted above where the slidable retainer (7570, 7770, 7870, 8970, 9070, 9170, 9270, 9770) is installed by snapping onto the skirt portion (6750, 7350, 7550, 7650, 7750, 7850, 8150, 9050, 9150, 9250, 9750) then sliding into engagement with the mounting foot (7601, 7701, 7801, 9101, 9201, 9701).

Array Trim

Referring now to FIGS. 98A-100, wherein like numerals refer to like structures, embodiments of an array trim and a skirt bracket are shown. Referring now to FIGS. 98A-98C, an array trim, such as array trim 9801, may include a front screen 9802, a top screen 9803, a lower screen 9804, a catch 9805, and a bracket slot 9806 as shown and described in FIG. 98B and others. The top screen 9803 may extend at a right angle from the top edge of the front screen 9802. The lower screen 9804 may extend from the bottom edge of the front screen 9802 at a forty-five degree angle, at an angle between one and forty-four degrees, at an angle between forty six and ninety degrees, or at another angle. Catch 9805 may extend from and curve under top screen 9803, extending toward the underside of front screen 9802. Catch 9805 may be the same width as top screen 9803 or may be inset from the outer edges of top screen 9803. Bracket slot 9806 may be formed in the space between top screen 9803 and catch 9805. Array trim 9801 may be formed of aluminum, an alloy, or another substance known to one skilled in the art. The array trim may flex or otherwise deform. The array trim may be of varying lengths, including but not limited to the length of a skirt bracket, described below. The top panel 9803, front panel 9802, and lower panel 9804 may be of varying dimensions. The array trim may have more or fewer panels to provide different aesthetic results. The array trim connects to a PV array, as described below, and provides improved aesthetics by concealing the gap between the array and the surface to which the array is installed.

Referring now to FIGS. 99A-99B, an embodiment of a skirt bracket is shown. A skirt bracket, such as skirt bracket 9907, may include a trim flange 9908, an upper lip 9909, a lower lip 9910, a front panel 9911, a rear lower panel 9912, a rear upper panel 9913, a bottom panel 9914, a top panel 9915, and a groove 9916. Top panel 9915 may extend at a ninety-degree angle from the top edge of front panel 9911, and bottom panel 9914 may extend at a ninety-degree angle from the bottom edge of front panel 9911 in the same direction as top panel 9915. The edge of top panel 9915 may then intersect rear upper panel 9913 at a ninety degree angle, such that rear upper panel 9913 extends vertically both above and below top panel 9915. Top lip 9909 may extend at a ninety-degree angle from the bottom edge of rear upper panel 9913, extending toward front panel 9911. Trim flange 9908 may extend at a ninety degree angle from the top edge of upper rear panel 9913, extending away from front panel 9911. Rear lower panel 9912 may extend at a ninety-degree angle from the edge of bottom panel 9914, extending upward toward upper rear panel 9913. Lower lip 9910 may then extend at a ninety-degree angle from the top edge of lower rear panel 9912, extending toward front panel 9911. The skirt bracket may be formed of aluminum, an alloy, or another substance known to one skilled in the art. The bracket may flex or otherwise deform. The skirt bracket may be of varying lengths. The various panels that comprise the skirt bracket may be of equal lengths or unequal lengths. The angles at which the various panels that comprise the skirt bracket meet may be greater than or less than ninety degrees. The dimensions of the various panels that comprise the skirt bracket may vary.

Referring now to FIG. 100, an array trim is shown connecting to a skirt bracket and a PV array. An array trim such as array trim 10001, which is similar to array trim 9801 as shown and described in FIG. 98A and others and to other array trims, may connect to (i) a skirt bracket such as skirt bracket 10007, which is similar to skirt bracket 9907 as shown and described in FIG. 99A and others and to other skirt brackets, and (ii) a PV array with (iii) a coupling, such as coupling 10027. Coupling 10027 may include first engaging portion 10028 and second engaging portion 10029. Coupling 10027 is similar to coupling 9416 as shown and described in FIG. 94 and others, as well as to other couplings. Array trim 10001 may connect to a PV array as follows. The trim flange 10008 of the skirt bracket 10007 may connect to the bracket slot 10006 of the array trim 10001. Coupling 10027 may then engage groove 10022 and groove 10016, connecting array trim 10001, skirt bracket 10007, coupling 10027, and groove 10022.

In summary, disclosed is a photovoltaic array, comprising a photovoltaic module (6720, 9717, 10320) having a frame (8021, 9021, 9321), a skirt bracket (9907, 10007), a skirt, screen, or screen type skirt (9801, 10001) removably connected to the skirt bracket (9907, 10007), and a coupling (10027) comprising a first engaging portion (10028) connected to the frame (8021, 9021, 9321) and a second engaging portion (10029) connected to the skirt bracket (9907, 10007) such that the coupling (10027) is adjustably positionable along a length of the frame (8021, 9021, 9321).

Abatement Screen

Referring now to FIGS. 101A-103, wherein like numerals refer to like structures, embodiments of the components of a pest abatement screen are shown. Referring now to FIG. 101, an abatement screen consists of a screen coupling such as screen coupling 10101 which includes (i) a mounting plate 10102 with one or more apertures 10103 and a bumper 10104 as well as (ii) a key portion 10106 with two or more teeth 10107A and 10107B. For the purpose of this paragraph, “up” or “upward” means skyward, “down” or “downward” means away from the sky, rear, back, or backward refers to the direction in which the key portion extends away from mounting plate, and “front” or “forward” refers to the opposite direction. Key portion 10106 may extend back from the center-top of the rear surface of the mounting plate 10102, or may extend back from another position on the mounting plate 10102. At the rear-most end of the key portion 10106 one tooth 10107A may extend vertically upward and one tooth 10107B may extend vertically downward. Mounting plate 10102 may extend downward from its connection point to key portion 10106, or may extend in another direction or multiple directions. Bumper 10104 may extend forward from mounting plate 10102 opposite the position from which key portion 10106 extends back from mounting plate 10102, or may extend forward from another position on mounting plate 10102, such that it creates a stopper surface 10105 facing downward. Bumper 10104 may take the form of a downward arc, a cube, a cubic rectangle, or another form that creates a stopper surface 10105. Aperture 10103A may appear where the mounting plate 10102 meets the key portion 10106 and may extend through both the mounting plate 10102 and the key portion 10106. Aperture 10103B may appear centered horizontally on the mounting plate 10102, or may appear elsewhere on mounting plate 10102. Screen coupling 10101 may be steel, aluminum, another metal, composite, plastic, or another material as known to one skilled in the art. Screen coupling 10101 may be 76 millimeters high (excluding teeth 10107A and 10107B), 70 millimeters high, 80 millimeters high, or another height. Screen coupling 10101 may be 50 millimeters wide, 40 millimeters wide, 60 millimeters wide, or another width. Screen coupling 10101 may be 40 millimeters deep from bumper 10104 to key portion 10106, 30 millimeters deep, 50 millimeters deep, or another depth. Referring now to FIG. 102, an abatement screen further consists of a screen such as screen 10208. Screen 10208 (i) may be a mesh with crisscrossing threads 10209 (for example and without limitation, threads running horizontally and vertically as shown and described in FIG. 102, though such threads may also extend at a forty-five degree angle or another angle, and may extend at the same angle or different angles) that create perforations 10213 ranging in size from 0.05 inches to 0.15 inches of length and/or width or of diameter, (ii) may be a panel with perforations, or (iii) may take another form as known to one skilled in the art. Screen 10208 may be aluminum or another metal, plastic, composite, or another material as known to one skilled in the art. Screen 10208 may be the length of the PV module to which it attaches, may be greater than the length of that PV module, or may be less than the length of that PV module.

Referring now to FIG. 103, an abatement screen is shown connected to a PV module. An abatement screen such as abatement screen 10310 may prevent or reduce the entry of pests and debris to the area beneath a PV module such as PV module 10320 (which is similar to PV module 6720 as shown and described in FIG. 67 and others, as well as to other PV modules) in order to prevent infestation, damage to electrical wires beneath the array, the accumulation of debris an accompanying risk of fire, or restriction of air-flow beneath PV module 10320.

Abatement screen 10310 may attach to PV module 10320 or a PV array as follows. Screen coupling 10301 is oriented with PV module 10320 such that the key portion 10306 faces the groove 10322 surrounding laminate 10314 and the teeth 10307A and 10307B extend parallel to the groove 10322. Key portion 10306 is then moved into the groove and the screen coupling is rotated such that the mounting plate 10302 angles downward and the teeth 10307A and 10307B become perpendicular to the groove 10322. The top-most portion of screen 10308 is then placed against stopper surface 10305 and the rear side of screen 10308 is placed against mounting plate 10302 such that aperture 10303B is aligned between the threads 10309 of screen 10308. A washer such as washer 10312 is then placed in front of screen 10308 and aligned with aperture 10303B, then a screw such as screw 10311 is placed into aperture 10303B and tightened to secure washer 10312 and screen 10308 to screen coupling 10301 and thus to PV module 10320, covering all of or a portion of the opening 10315 beneath the PV module 10320. Screen 10308 may be vertical, may attach at a forty-five degree angle, may attach at an angle between forty-five and ninety degrees, or may attach at an angle between forty five and zero degrees. Screw 10311 may be a flat-head screw, Phillips head screw, or other screw as known to one with skill in the art. Washer 10312 may be a flat washer, spring washer, or other washer as known to one with skill in the art.

In summary, disclosed is a photovoltaic module, comprising a frame (8021, 9021, 9321) supporting a photovoltaic laminate (10314), a screen coupling (10101, 10301) connected to a groove (6722, 10322) in the frame (8021, 9021, 9321), the screen coupling (10101, 10301) comprising a key portion (10106), the key portion (10106) permitting insertion of the key portion (10106) into a photovoltaic module (6720, 9717, 10320) frame (8021, 9021, 9321) in a first position and preventing rotation of the key portion (10106) inside the frame (8021, 9021, 9321) in a second position, and a screen (10208, 10308) connected to the screen coupling (10101, 10301). The screen (10208, 10308) covers at least a portion of an opening (6758, 10315) beneath the photovoltaic module (6720, 9717, 10320) when the photovoltaic module (6720, 9717, 10320) is mounted to a support structure (9726).

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions, and sub-combinations as are within their true spirit and scope.

What is claimed as invention is:

1. An installed photovoltaic array comprising:
a photovoltaic module;
a skirt covering at least a portion of an opening beneath said photovoltaic module;
a spring bracket connecting said skirt to said photovoltaic module, said spring bracket comprising a base portion, an arm extending outward from said base portion, and a retaining portion near an end of said arm;
wherein said arm acts as a flexible lever reducing an input force required to rotate said base portion into an installed position and flexing to enable said retaining portion to lock onto said photovoltaic module and said skirt.

2. The installed photovoltaic array of claim 1, wherein said retaining portion bears against at least one of said photovoltaic module and said skirt with a spring force, said spring force substantially resulting from said flexing of said arm.

3. The installed photovoltaic array of claim 1, wherein said retaining portion comprises a tab, said tab at least partially retained by at least one of said photovoltaic module and said skirt in an installed position.

4. The installed photovoltaic array of claim 1, wherein said arm comprises an elongate form extending in a direction substantially parallel to a plane of a top surface of a light receiving side of a photovoltaic laminate of said photovoltaic module.

5. The installed photovoltaic array of claim 1, wherein said spring bracket connects to a groove in a frame of said photovoltaic module.

6. The installed photovoltaic array of claim 1, wherein said spring bracket connects to a groove in said skirt.

7. The installed photovoltaic array of claim 1, wherein said spring bracket captures at least a portion of said photovoltaic module.

8. A photovoltaic array skirt, comprising:
a skirt portion covering at least a portion of an opening beneath a photovoltaic module;
a mounting foot connecting said skirt portion to a support structure; and
a slidable retainer at least partially connecting said skirt portion to said mounting foot;
wherein said slidable retainer is laterally slidable along said skirt portion to disengage from said mounting foot and comprises a retaining feature, said retaining feature enabling an adjustably secure connection of said slidable retainer to said skirt portion prior to connecting said slidable retainer to said mounting foot.

9. The photovoltaic skirt of claim 8, wherein said slidable retainer is installed by snapping onto said skirt portion then sliding into engagement with said mounting foot.

10. A photovoltaic array, comprising:
a photovoltaic module having a frame;
a skirt removably connected to said skirt bracket; and
a coupling comprising a first engaging portion connected to said frame and a second engaging portion connected to said skirt bracket;
wherein said coupling is adjustably positionable along a length of said frame.

11. A photovoltaic module, comprising:
a frame supporting a photovoltaic laminate;
a screen coupling connected to a groove in said frame, said screen coupling comprising a key portion, said key portion permitting insertion of said key portion into a photovoltaic module frame in a first position and preventing rotation of said key portion inside said frame in a second position; and
a screen connected to said screen coupling;
wherein said screen covers at least a portion of an opening beneath said photovoltaic module when said photovoltaic module is mounted to a support structure.
